(19) United States
(12) Patent Application Publication
(10) Pub. No.: US 2025/0081514 A1
(43) Pub. Date: Mar. 6, 2025

(54) SEMICONDUCTOR DEVICE

(71) Applicant: Samsung Electronics Co., Ltd., Suwon-si (KR)

(72) Inventors: Gyuhwan Oh, Suwon-si (KR); Seokhan Park, Suwon-si (KR); Bowon Yoo, Suwon-si (KR); Jinwoo Han, Suwon-si (KR)

(21) Appl. No.: 18/650,251

(22) Filed: Apr. 30, 2024

(30) Foreign Application Priority Data
Aug. 29, 2023 (KR) 10-2023-0113972

(51) Int. Cl. H01L 29/78; H01L 29/10; H10B 12/00

(52) U.S. Cl. CPC H10D 30/63; H10B 12/315; H10B 12/482; H10B 12/488; H10D 62/292

(57) ABSTRACT

A semiconductor device includes a back gate line that is on a substrate and extends in a first direction, a plurality of channel structures that are on side walls of the back gate line and spaced apart from each other in a second first direction that intersects the first direction, a word line that at least partially surrounds the plurality of channel structures, and a bit line on a lower surface of each of the plurality of channel structures, where each of the plurality of channel structures includes: a first side wall facing the word line, and a second side wall that faces the back gate line and contacts an edge of the first side wall, where the first side wall is curved, and where the second side wall is flat.

### CROSS-REFERENCE TO RELATED APPLICATION

This application is based on and claims priority under 35 U.S.C. § 119 to Korean Patent Application No. 10-2023-0113972, filed on Aug. 29, 2023, in the Korean Intellectual Property Office, the disclosure of which is incorporated by reference herein in its entirety.

### TECHNICAL FIELD

The present disclosure relates to a semiconductor device, and more particularly, to a semiconductor device including a vertical channel transistor structure.

### BACKGROUND

As miniaturization, multifunctionalities, and high performance of electronic products are desired, semiconductor devices may have higher capacities and higher integration. According to the down-scaling of semiconductor devices, many studies are underway. As a part of these studies, vertical channel transistors vertically formed on semiconductor substrates, rather than planar channel transistors horizontally formed on semiconductor substrates, have been introduced.

### SUMMARY

It is an object of the technical idea of the present disclosure to provide a vertical channel transistor including a back gate line and including a channel structure having a shape capable of reducing a floating body effect, and a semiconductor device including the vertical channel transistor.

Also, objects of the technical idea of the present disclosure are not limited to the above-mentioned object, and other objects will be clearly understood by one of ordinary skill in the art from the following descriptions.

To solve the above-described object, a technical idea of the present disclosure may provide a semiconductor device including a back gate line that is on a substrate and extends in a first direction, a plurality of channel structures that are on side walls of the back gate line and spaced apart from each other in a second first direction that intersects the first direction, a word line that at least partially surrounds the plurality of channel structures, and a bit line on a lower surface of each of the plurality of channel structures, where each of the plurality of channel structures includes: a first side wall facing the word line, and a second side wall that faces the back gate line and contacts an edge of the first side wall, where the first side wall is curved, and where the second side wall is flat.

To solve the above-described object, a technical idea of the present disclosure may provide a semiconductor device including a bit line that is on a substrate and extends in a first horizontal direction, a plurality of channel structures on the bit line, a back gate line that is on first side walls of the plurality of channel structures and extends in a second horizontal direction that intersects the first horizontal direction, and a word line that is on second side walls of the plurality of channel structures, at least partially surrounds the plurality of channel structures, and extends in the second horizontal direction, where: each of the first side walls faces the word line, each of the second side walls faces the back gate line and is spaced apart from a respective first side wall from among the first side walls, each of the plurality of channel structures includes a third side wall that is between and contacts the respective first side wall and a respective second side wall, each of the first side walls is curved, each of the second side walls extends in the second horizontal direction, and each of the third side walls extends in the first horizontal direction.

To solve the above-described object, a technical idea of the present disclosure may provide a semiconductor device including: a substrate, a bit line that is on the substrate and extends in a first horizontal direction, a plurality of channel structures that are electrically connected to the bit line and extend in a vertical direction from an upper surface of the bit line, a back gate line that is on first side walls of the plurality of channel structures and extends in a second horizontal direction that intersects the first horizontal direction, a back gate insulating layer between the plurality of channel structures and the back gate line, a word line that is on second side walls of the plurality of channel structures, at least partially surrounds the plurality of channel structures, and extends in the second horizontal direction, a gate dielectric layer between the plurality of channel structures and the word line, a conductive contact pattern that is on the plurality of channel structures and is electrically connected to a first channel structure among the plurality of channel structures, and a capacitor structure that is on the conductive contact pattern and electrically connected to the conductive contact pattern, where each of the plurality of channel structures includes a first side wall that contacts the gate dielectric layer and a second side wall that contacts the back gate insulating layer, where the first side wall is curved, and where the second side wall is flat.

### BRIEF DESCRIPTION OF THE DRAWINGS

The above and other aspects of the present disclosure will become more apparent by describing in detail embodiments thereof, with reference to the accompanying drawings, in which:

FIG. 1A is a diagram for describing a semiconductor device according to embodiments of the present disclosure;

FIG. 1B is a cross-sectional view of the semiconductor device taken along line A1-A1′ of FIG. 1A;

FIG. 1C is a cross-sectional view of the semiconductor device taken along line B1-B1′ of FIG. 1A;

FIG. 1D is a perspective view for describing a semiconductor device according to embodiments of the present disclosure;

FIG. 2 is a diagram for describing a semiconductor device according to embodiments of the present disclosure;

FIG. 3 is a diagram for describing a semiconductor device according to embodiments of the present disclosure;

FIG. 4 is a diagram for describing a semiconductor device according to embodiments of the present disclosure;

FIG. 5A is a diagram for describing a semiconductor device according to embodiments of the present disclosure;

FIG. 5B is a cross-sectional view of the semiconductor device taken along line A2-A2′ of FIG. 5A;

FIG. 6A is a diagram for describing a semiconductor device according to embodiments of the present disclosure;

FIG. 6B is a cross-sectional view of the semiconductor device taken along line A3-A3′ of FIG. 6A; and

FIGS. 7A, 7B, 8A, 8B, 9A, 9B, 10, 11, 12A, 12B, 13A, 13B, 14, 15, 16, 17, and 18 show sequential processes of a method for manufacturing a semiconductor device according to embodiments of the present disclosure.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and case of description, the present disclosure is not limited to the illustrated sizes and thicknesses. In the drawings, the thickness of layers, films, panels, regions, etc., are exaggerated for clarity. In the drawings, for better understanding and case of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, embodiments will be described in detail with reference to the accompanying drawings. In the drawings, like components will be assigned like reference numerals, and overlapping descriptions thereof will be omitted.

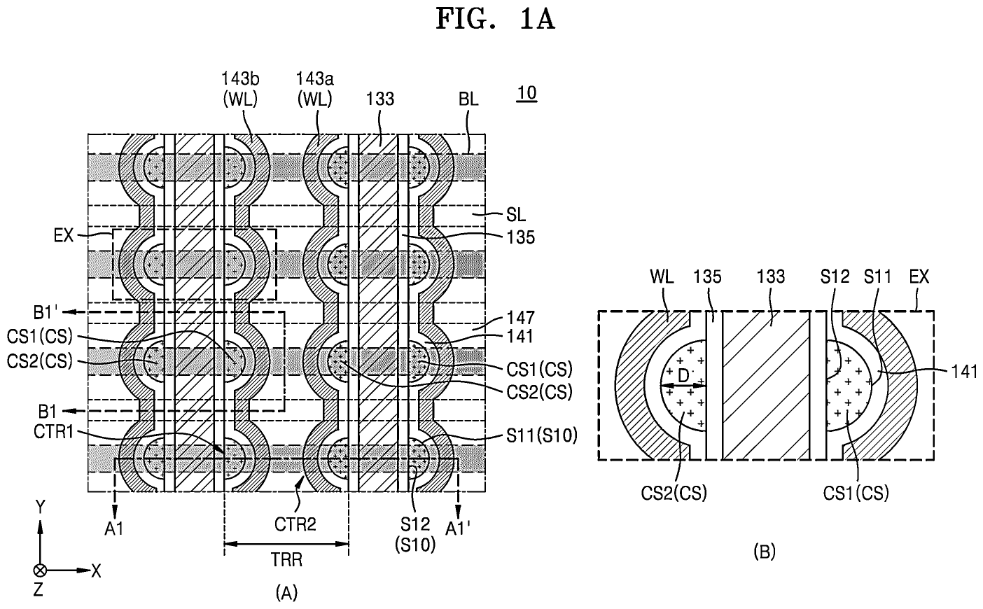

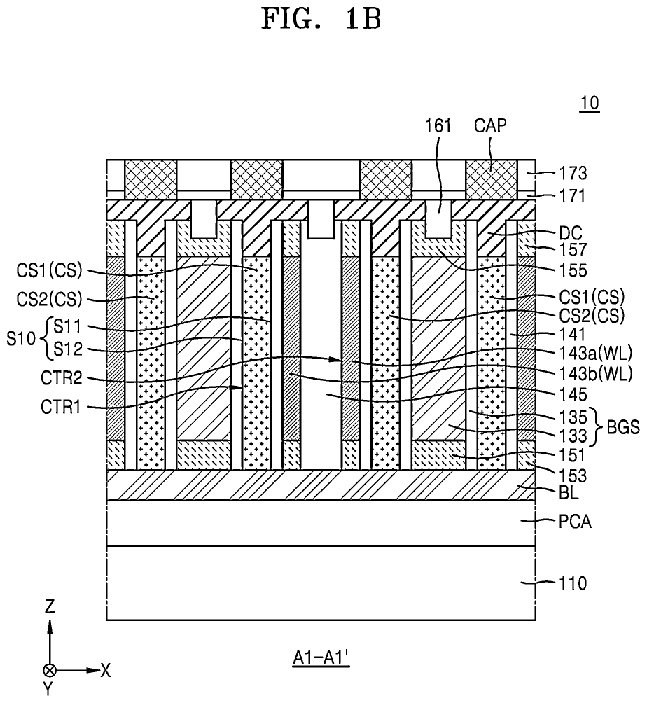

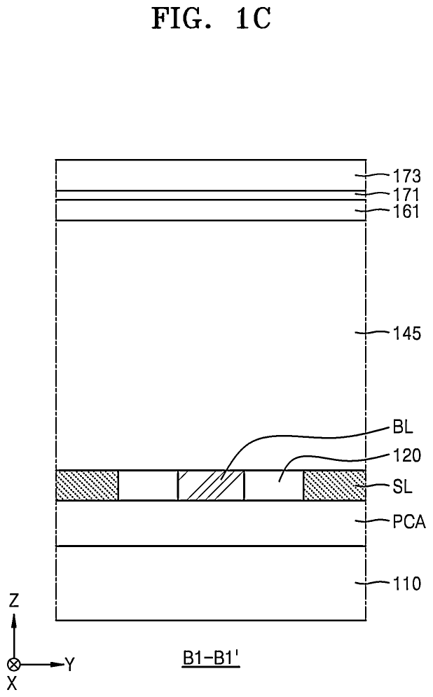

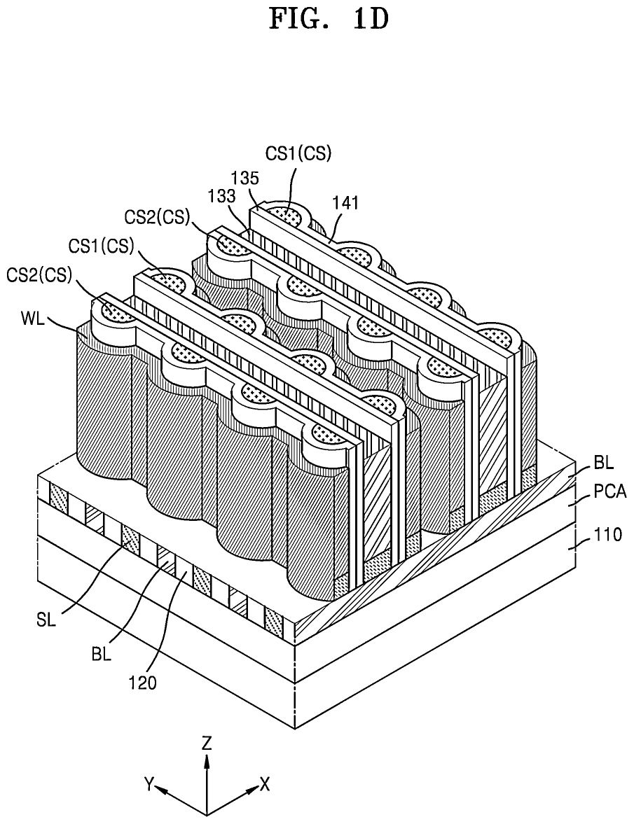

FIG. 1A is a diagram for describing a semiconductor device 10 according to embodiments of the present disclosure. FIG. 1B is a cross-sectional view of the semiconductor device 10 taken along line A1-A1′ of FIG. 1A. FIG. 1C is a cross-sectional view of the semiconductor device 10 taken along line B1-B1′ of FIG. 1A. FIG. 1D is a perspective view for describing the semiconductor device 10 according to embodiments of the present disclosure.

Referring to FIGS. 1A, 1B, 1C, and 1D, the semiconductor device 10 may include a substrate 110, a printed circuit assembly PCA positioned on the substrate 110, and a plurality of bit lines BL and a plurality of shielding layers SL positioned on the printed circuit assembly PCA.

According to embodiments, the substrate 110 may include silicon, for example, single-crystal silicon, poly-crystalline silicon, or amorphous silicon. According to some embodiments, the substrate 110 may include at least one selected from among germanium (Ge), silicon germanium (SiGe), silicon carbide (SiC), gallium arsenide (GaAs), indium arsenide (InAs), or indium phosphide (InP). According to embodiments, the substrate 110 may include a conductive area, for example, a well doped with impurities or a structure doped with impurities.

In the specification of the present disclosure, a direction in which the substrate 110 extends may be a first horizontal direction (e.g., a X direction), another direction in which the substrate 110 extends may be a second horizontal direction (e.g., an Y direction), and a direction intersecting the first horizontal direction (e.g., the X direction) and the second horizontal direction (e.g., the Y direction) may be a vertical direction (e.g., a direction Z).

According to embodiments, the printed circuit assembly PCA may further include various active elements, such as transistors, and various passive elements, such as capacitors, resistors, and inductors. According to embodiments, the printed circuit assembly PCA positioned on the substrate 110 may be omitted, and in this case, the printed circuit assembly PCA may be positioned at another area as opposed to an area shown in FIGS. 1A, 1B, 1C, and 1D.

The plurality of bit lines BL may be connected to at least one peripheral circuit among a plurality of peripheral circuits included in the printed circuit assembly PCA. According to embodiments, the plurality of peripheral circuits may include a sub-word line driver block (SWD), a sense amplifier block (S/A), and/or a control logic, although the present disclosure is not limited thereto. For example, the plurality of peripheral circuits may include a N-channel metal oxide semiconductor (NMOS) transistor and a P-channel metal oxide semiconductor (PMOS) transistor. Each of the plurality of shielding layers SL may be floated.

The plurality of bit lines BL may be spaced apart from the plurality of shielding layers SL in the second horizontal direction (e.g., the Y direction) on the substrate 110, and the plurality of bit lines BL and the plurality of shielding layers SL may extend in the first horizontal direction (e.g., the X direction) that is perpendicular to the second horizontal direction (e.g., the Y direction). The plurality of bit lines BL and the plurality of shielding layers SL may extend in parallel in the first horizontal direction (e.g., the X direction). According to embodiments, the plurality of bit lines BL and the plurality of shielding layers SL may be alternately arranged with each other. For example, any bit line BL from among the plurality of bit lines BL may be positioned between two shielding layers SL that are adjacent to the bit line BL, and any shielding line SL from among the plurality of shielding layers SL may be positioned between two bit lines BL that are adjacent to the shielding line SL.

Any bit line BL from among the plurality of bit lines BL may be insulated from two shielding layers SL being adjacent to the bit line BL by an interlayer insulating pattern 120. Also, any shielding layer SL from among the plurality of shielding layers SL may be insulated from two bit lines BL being adjacent to the shielding layer SL by an interlayer insulating pattern 120.

According to embodiments, the plurality of bit lines BL may be formed of titanium (Ti), titanium nitride (TiN), tantalum (Ta), tantalum nitride (TaN), molybdenum (Mo), ruthenium (Ru), tungsten (W), tungsten nitride (WN), cobalt (Co), nickel (Ni), titanium silicon (TiSi), titanium silicon nitride (TiSiN), tungsten silicon (WSi), tungsten silicon nitride (WSiN), tantalum silicon (TaSi), tantalum silicon nitride (TaSiN), ruthenium titanium nitride (RuTiN), cobalt silicon (CoSi), nickel silicon (NiSi), polysilicon, or a combination thereof, although the present disclosure is not limited thereto. According to embodiments, the plurality of shielding layers SL may be formed of tungsten (W), aluminum (A1), copper (Cu), or a combination thereof, although the present disclosure is not limited thereto. According to embodiments, the plurality of shielding layers SL may include a conductive layer formed of W, A1, Cu, or a combination thereof, and an air gap or void formed inside the conductive layer.

On each bit line BL, a back gate structure BGS may be positioned. The back gate structure BGS may include a back gate line 133 and a back gate insulating layer 135 at least partially surrounding a side wall of the back gate line 133.

Two or more back gate lines 133 may be provided in such a way as to extend in one direction. For example, the plurality of back gate lines 133 may be spaced apart from each other in the first horizontal direction (e.g., the X direction), and each of the plurality of back gate lines 133 may extend in the second horizontal direction (e.g., the Y direction). According to embodiments, the back gate lines 133 may include a metal (for example, Mo, Ru, and W), a metal nitride (for example, TiN, TaN, and WN), or a conductive material (for example, metal silicide).

The back gate insulating layer 135 may cover or overlap the side wall of the back gate line 133 and extend conformally along the side wall of the back gate line 133. According to embodiments, the back gate insulating layer 135 may include an oxide, such as silicon oxide. Alternatively, the back gate insulating layer 135 may include a metal oxide having a high dielectric constant, such as hafnium oxide and zirconium oxide, and have a multilayer structure including a first layer being in contact with the side wall of the back gate line 133 and a second layer including a silicon oxide and being in contact with a side wall of the first layer.

A plurality of channel structures CS may be positioned on the back gate insulating layer 135.

The plurality of channel structures CS may be positioned at one side of the back gate line 133 and arranged along the direction in which the back gate line 133 extends. The plurality of channel structures C may be spaced apart from each other along a side wall of the back gate insulating layer 135.

The plurality of channel structures CS may include a plurality of first channel structures CS1 and a plurality of second channel structures CS2, wherein the plurality of first channel structures CS1 may be spaced apart from the plurality of second channel structures CS2 with the back gate line 133 in between. The plurality of first channel structures CS1 may face one side wall of the back gate line 133, and the plurality of second channel structures CS2 may face another side wall of the back gate line 133. The plurality of first channel structures CS1 may be arranged to be spaced apart from each other along the side wall of the back gate line 133, and the plurality of second channel structures CS2 may be arranged to be spaced apart from each other along the other side wall of the back gate line 133. The plurality of first channel structures CS1 may be arranged to be symmetrical to the plurality of second channel structures CS2 with the back gate line 133 in between. The plurality of first channel structures CS1 and the plurality of second channel structures CS2 may be arranged in a direction (for example, the first horizontal direction (e.g., the X direction)) intersecting the direction in which the back gate line 133 extends.

According to embodiments, each of the plurality of channel structures CS may be in contact with a bit line BL at the lower surface to be electrically connected to the bit line BL. However, lower structures of the plurality of channel structures CS may be various according to processes, without being limited to those shown. For example, a plurality of bit line contacts (not shown) may be positioned between the plurality of channel structures CS and the bit line BL, and in this case, an insulating layer (not shown) surrounding side walls of the plurality of bit line contacts may be provided.

Each of the plurality of channel structures CS may include a first side wall S11 facing the back gate insulating layer 135, and a second side wall S12 connected to the first side wall S11 and extending on the back gate insulating layer 135. The first side wall S11 of the channel structure CS may be in contact with an edge of the second side wall S12 and spaced apart from a remaining portion of the second side wall S12 except for the edge of the second side wall S12.

According to embodiments, the first side wall S11 of the channel structure CS may be curved. For example, the first side wall S11 of the channel structure CS may have a circular-arc shape in a cross-sectional view. The second side wall S12 of the channel structure CS may have a line shape extending along the back gate insulating layer 135. According to embodiments, the first side wall S11 of the channel structure CS may be curved, and the second side wall S12 of the channel structure CS may be flat. According to embodiments, an entirety of the first side wall S11 of the channel structure CS may be curved. More specifically, the first side wall S11 of the channel structure CS may include no flat portion and the entire of the first side wall S11 may be curved.

According to embodiments, a horizontal width D of the channel structure CS may be constant at different levels in the vertical direction (e.g., the Z direction). For example, a first horizontal width of an upper portion of the channel structure CS may be equal to a second horizontal width of a lower portion of the channel structure CS. According to embodiments, the channel structure CS may have a semi-circular pillar shape. According to embodiments, the horizontal width D of the channel structure CS may range from 5 nanometers to 10 nanometers.

According to embodiments, because the first channel structure CS1 is symmetrical to the second channel structure CS2 with respect to the back gate line 133, a first side wall S11 of the first channel structure CS1 may also be symmetrical to a first side wall S11 of the second channel structure CS2 with respect to the back gate line 133. For example, the first side wall S11 of the first channel structure CS1 may have a circular-arc shape in a cross-sectional view facing one side of the back gate line 133, and in this case, the first side wall S11 of the second channel structure CS2 may also have a circular-arc shape in a cross-sectional view facing another side of the back gate line 133 to be symmetrical to the first side wall S11 of the first channel structure CS1.

According to embodiments, the plurality of channel structures CS may include a semiconductor material or an oxide semiconductor material. The semiconductor material may include, for example, single-crystal silicon or polysilicon. The oxide semiconductor material may include at least one metal element selected from among, for example, indium (In), gallium (Ga) or zinc (Zn), and may include at least one among, for example, InGaZnOx (IGZO), SN-doped InGaZnOx (SN-doped IGZO), W-doped InGaZnOx (W-doped IGZO), or InZnOx (IZO). In addition, IGZO may include at least one among single crystalline IGZO, polycrystalline IGZO, spinel IGZO, or C-axis aligned crystalline (CAAC) IGZO.

A gate dielectric layer 141 may be positioned on the plurality of channel structures CS. The gate dielectric layer 141 may cover or overlap side walls of the plurality of channel structures CS and a portion not covered or overlapped by the plurality of channel structures CS in a side wall of the back gate insulating layer 135. The gate dielectric layer 141 may extend conformally on the side walls of the plurality of channel structures CS and the portion not covered or overlapped by the plurality of channel structures CS in the side wall of the back gate insulating layer 135.

According to embodiments, a side wall of a portion covering or overlapping the plurality of channel structures CS in the gate dielectric layer 141 may be curved, for example, a circular-arc shape in a cross-sectional view to correspond to the side walls of the plurality of channel structures CS. Also, a side wall of a remaining portion of the gate dielectric layer 141, except for the portion covering or overlapping the plurality of channel structures CS, that is, a side wall of the portion covering or overlapping the back gate insulating layer 135 in the gate dielectric layer 141 may have a line shape. According to embodiments, the side wall of the portion covering or overlapping the plurality of channel structures CS in the gate dielectric layer 141 may be curved, and the side wall of the remaining portion of the gate dielectric layer 141, except for the portion covering or overlapping the plurality of channel structures CS, that is, the side wall of the portion covering or overlapping the back gate insulating layer 135 in the gate dielectric layer 141 may be flat.

According to embodiments, the gate dielectric layer 141 may be formed of at least one selected from among a ferroelectric material or a high-k dielectric material having a greater dielectric constant than silicon oxide. According to embodiments, the gate dielectric layer 141 may include at least one material selected from among hafnium oxide (HfO), hafnium silicate (HfSiO), hafnium oxynitride (HfON), hafnium silicon oxynitride (HfSiON), lantanium oxide (LaO), lantanium aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium tantalate bismuth (STB), bismuth ferrite oxide (BFO), strontium titanium oxide (SrTiO), yttrium oxide (YO), aluminum oxide (AlO), or lead scandium tatalum oxide (PbScTaO).

A word line WL may be positioned on the gate dielectric layer 141. The word line WL may cover or overlap a side wall of the gate dielectric layer 141 and extend along the side wall of the gate dielectric layer 141. A portion surrounding the plurality of channel structures CS in the word line WL may be curved, for example, a circular-arc shape in a cross-sectional view. Also, a remaining portion of the word line WL, except for the portion surrounding the plurality of channel structures CS, may have a line shape extending along the side wall of the gate dielectric layer 141. According to embodiments, a side wall of the portion surrounding the plurality of channel structures CS in the word line WL may be curved, and a side wall of the remaining portion of the word line WL except for the portion surrounding the plurality of channel structures CS may be flat.

According to embodiments, the word line WL may include Ti, TiN, Ta, TaN, W, WN, TiSiN, WSiN, polysilicon, or a combination thereof.

In any one back gate line 133 selected from among the plurality of back gate lines 133 and another back gate line 133 being adjacent to the one back gate line 133, a back gate insulating layer 135, a first channel structure CS1, a gate dielectric layer 141, and a word line WL may be arranged on one side, and on another side, a back gate insulating layer 135, a second channel structure CS2, a gate dielectric layer 141, and a word line WL may be arranged.

The back gate line 133 may extend from one side of the plurality of channel structures CS, and the word line WL may extend from other sides of the plurality of channel structures CS, with the plurality of channel structures CS in between. The first wall S11 of each of the plurality of channel structures CS may face the side wall of the word line WL, and the second wall S12 of each of the plurality of channel structures CS may face the side wall of the back gate line 133. The back gate insulating layer 135 may be positioned between the back gate line 133 and the plurality of channel structures CS, and the gate dielectric layer 141 may be positioned between the word line WL and the plurality of channel structures CS.

According to embodiments, because the first channel structures CS1 are symmetrical to the second channel structures CS2 with respect to the back gate line 133, the gate dielectric layer 141 and the word line WL covering or overlapping the first channel structures CS1 may be symmetrical to the gate dielectric layer 141 and the word line WL covering or overlapping the second channel structures CS2 with respect to the back gate line 133. That is, the gate dielectric layer 141 and the word line WL facing one side of the back gate line 133 may be symmetrical to the gate dielectric layer 141 and the word line WL facing another side of the back gate line 133 with respect to the back gate line 133.

A word line (WL) 143a positioned on one side of any one back gate line 133 selected from among the plurality of back gate lines 133 may be spaced apart from a word line (WL) 143b positioned on another side of another back gate line 133 being adjacent to the one back gate line 133.

An insulating partition wall 145 may extend in the vertical direction (e.g., the Z direction) on an upper surface of the bit line B, and may be positioned between the word line (WL) 143a positioned on the one side of the one back gate line 133 selected from among the plurality of back gate lines 133 and the word line (WL) 143b positioned on the other side of the other back gate line 133 being adjacent to the one back gate line 133.

The insulating partition wall 145 may insulate the word line (WL) 143a positioned on the one side of the one back gate line 133 selected from among the plurality of back gate lines 133 from the word line (WL) 143b positioned on the other side of the other back gate line 133 being adjacent to the one back gate line 133. According to embodiments, the insulating partition wall 145 may include a silicon oxide, a silicon nitride, or a combination thereof.

A lower back gate capping layer 151 may be positioned at a lower portion of the back gate line 133. Two or more lower back gate capping layers 151 may be provided, and the plurality of lower back gate capping layers 151 may be spaced apart from each other in the first horizontal direction (e.g., the X direction) to be positioned at lower portions of the corresponding ones of the plurality of back gate lines 133. The plurality of lower back gate capping layers 151 may extend in the second horizontal direction (e.g., the Y direction) at the lower portions of the corresponding ones of the plurality of back gate lines 133. According to embodiments, the lower back gate capping layers 151 may include a silicon oxide, a silicon nitride, or a combination thereof.

The lower back gate capping layer 151 may be positioned between the back gate line 133 and the bit lines BL to prevent the back gate line 133 from contacting the bit line BL. That is, the back gate line 133 may be spaced apart from the bit line BL with the lower back gate capping layer 151 in between.

An upper back gate capping layer 155 may be positioned at an upper portion of the back gate line 133. Two or more upper back gate capping layers 155 may be provided, and the plurality of upper back gate capping layers 155 may be spaced apart from each other in the first horizontal direction (e.g., the X direction) to be positioned at upper portions of the corresponding ones of the plurality of back gate lines 133. The plurality of upper back gate capping layers 155 may extend in the second horizontal direction (e.g., the Y direction) at the upper portions of the corresponding ones of the plurality of back gate lines 133. According to embodiments, the upper back gate capping layers 155 may include a silicon oxide, a silicon nitride or a combination thereof.

The upper back gate capping layer 155 may be positioned at the upper portion of the back gate lines 133. More specifically, the upper back gate capping layer 155 may be positioned between the back gate line 133 and a conductive contact pattern DC above the back gate line 133 to prevent the back gate line 133 from contacting the conductive contact pattern DC. That is, the back gate line 133 may be spaced apart from the conductive contact pattern DC with the upper back gate capping layer 155 in between.

The lower back gate capping layer 151 and the upper back gate capping layer 155 may be positioned between a back gate insulating layer 135 positioned on one side of the back gate line 133 and a back gate insulating layer 135 positioned on another side of the back gate line 133. The lower back gate capping layer 151 may cover or overlap a lower side wall of the back gate insulating layer 135 positioned on the one side of the back gate line 133 and a lower side wall of the back gate insulating layer 135 positioned on the other side of the back gate line 133. The upper back gate capping layer 155 may cover or overlap an upper side wall of the back gate insulating layer 135 positioned on the one side of the back gate line 133 and an upper side wall of the back gate insulating layer 135 positioned on the other side of the back gate line 133.

At a lower portion of each word line WL, a lower word line capping layer 153 may be positioned. The lower word line capping layer 153 may be positioned between the word line WL and a bit line BL to prevent the word line WL from contacting the bit line BL. According to embodiments, the lower word line capping layer 153 may include the same material as the lower back gate capping layer 151. For example, the lower word line capping layer 153 may include a silicon oxide, a silicon nitride, or a combination thereof.

At an upper portion of the word line WL, an upper word line capping layer 157 may be positioned. More specifically, the upper word line capping layer 157 may be positioned between the word line WL and a conductive contact pattern DC positioned above the word line WL to prevent the word line WL from contacting the conductive contact pattern DC. According to embodiments, the upper word line capping layer 157 may include the same material as the upper back gate capping layer 155. For example, the upper word line capping layer 157 may include a silicon oxide, a silicon nitride, or a combination thereof.

The lower word line capping layer 153 and the upper word line capping layer 157 may be positioned between the gate dielectric layer 141 and the insulating partition wall 145. The lower word line capping layer 153 may cover or overlap the lower side wall of the gate dielectric layer 141 and the lower side wall of the insulating partition wall 145, and the upper word line capping layer 157 may cover or overlap the upper side wall of the gate dielectric layer 141 and the upper side wall of the insulating partition wall 145. A lower portion of the side wall of the insulating partition wall 145 may be covered or overlapped by the lower word line capping layer 153, an upper portion of the side wall of the insulating partition wall 145 may be covered or overlapped by the upper word line capping layer 157, and a remaining portion of the side wall of the insulating partition wall 145 may be covered or overlapped by the word line WL. As a result, the word line WL may be at least partially surrounded by the gate dielectric layer 141, the lower word line capping layer 153, the insulating partition wall 145, and the upper word line capping layer 157.

At a transistor region TRR, a plurality of transistors may be arranged. The plurality of transistors may include a first cell transistor CTR1 and a second cell transistor CTR2 facing the first cell transistor CTR1 in the first horizontal direction (e.g., the X direction), wherein the first cell transistor CTR1 may be spaced apart from the second cell transistor CTR2 with the insulating partition wall 145 in between.

Any one of the channel structure CS selected from among the plurality of channel structures CS, and a gate dielectric layer 141 and a word line WL being adjacent to the channel structure CS may constitute the first cell transistor CTR1, and another channel structure CS spaced apart from the one channel structure CS selected from among the plurality of channel structures CS with the insulating partition wall 145 in between, and a gate dielectric layer 141 and a word line WL being adjacent to the other channel structure CS may constitute the second cell transistor CTR2.

For example, the first channel structure CS1, the word line (WL) 143b being adjacent to the first channel structure CS1, and the gate dielectric layer 141 positioned between the first channel structure CS1 and the word line (WL) 143b may constitute the first cell transistor CTR1, and the second channel structure CS2 spaced apart from the first channel structure CS1 with the insulating partition wall 145 in between, the word line (WL) 143a being adjacent to the second channel structure CS2, and the gate dielectric layer 141 positioned between the second channel structure CS2 and the word line (WL) 143b may constitute the second cell transistor CTR2. The first channel structure CS1 may be connected to the second channel structure CS2 at the lower portions of the word lines WL, in one variation, the first cell transistor CTR1 and the second cell transistor CTR2 may share the first channel structure CS1 and the second channel structure CS2.

A plurality of conductive contact patterns DC may be positioned above the plurality of channel structures CS. Each of the plurality of conductive contact patterns DC may be connected to any one channel structure CS selected from among the plurality of channel structures CS. Each of the plurality of conductive contact patterns DC may cover or overlap the back gate insulating layer 135 and at least one portion of an upper surface of the upper back gate capping layer 155, and cover or overlap the gate dielectric layer 141, the insulating partition wall 145, and at least one portion of an upper surface of the upper word line capping layer 157.

Portions overlapping with the plurality of channel structures CS in lower surfaces of the plurality of conductive contact patterns DC may be positioned at a different level in the vertical direction (e.g., the Z direction) from remaining portions of the lower surfaces of the plurality of conductive contact patterns DC. For example, the portions overlapping with the plurality of channel structures CS in the lower surfaces of the plurality of conductive contact patterns DC may be positioned at a lower level in the vertical direction (e.g., the Z direction) than the remaining portions of the lower surfaces of the plurality of conductive contact patterns DC. That is, the portions overlapping with the plurality of channel structures CS in the plurality of conductive contact patterns DC may protrude or extend toward the plurality of channel structures CS compared to the remaining portions of the plurality of conductive contact patterns DC.

The plurality of conductive contact patterns DC may be arranged regularly at constant intervals in the first horizontal direction (e.g., the X direction) and the second horizontal direction (e.g., the Y direction) with respect to a plane (for example, X-Y plane) of the substrate 110, although not shown. For example, the plurality of conductive contact patterns DC may be arranged in a matrix structure or in a honeycomb structure.

According to embodiments, each of the plurality of conductive contact patterns DC may be a metal-containing layer. According to embodiments, each of the plurality of conductive contact patterns DC may be formed of Ti, TiN, Ta, TaN, Mo, Ru, W, WN, TiSiN, WSiN, polysilicon or a combination thereof. For example, each of the plurality of conductive contact patterns DC may have a laminated structure of a conductive barrier layer formed of TiN and a conductive layer formed of W. Alternatively, for example, each of the plurality of conductive contact patterns DC may include a lower contact plug, an ohmic contact plug, and an upper contact plug. The lower contact plug may include, for example, polysilicon doped with n-type impurities or p-type impurities, the ohmic contact plug may include, for example, metal silicide, such as cobalt silicide, nickel silicide, and titanium silicide, and the upper contact plug may include a conductive material, such as metal, metal nitride, and metal silicide.

The plurality of conductive contact patterns DC may be spaced apart from each other by a separation insulation pattern 161. The plurality of conductive contact patterns DC may be divided into a conductive contact pattern DC connected to the first cell transistor CTR1 and a conductive contact pattern DC connected to the second cell transistor CTR2, respectively, by the separation insulation pattern 161. According to embodiments, at least an area of a side wall of the separation insulation pattern 161 may be covered or overlapped by the conductive contact patterns DC, and a remaining area of the side wall of the separation insulation pattern 161 may be covered or overlapped by the insulating partition wall 145 or the upper back gate capping layer 155. The separation insulation pattern 161 may penetrate or extend into at least one portion of the insulating partition wall 145 or the upper back side capping layer 155. According to embodiments, the separation insulation pattern 161 may include a silicon oxide, a silicon nitride, or a combination thereof.

The semiconductor device 10 may further include a capacitor structure CAP connected to one of the conductive contact patterns DC. An etch stop layer 171 and a capacitor insulating layer 173 may be applied in order on the plurality of conductive contact patterns DC and the separation insulation pattern 161, and the capacitor structure CAP may penetrate or extend into the capacitor insulating layer 173 and the etch stop layer 171 in the vertical direction (e.g., the Z direction) to be connected to any one conductive contact pattern DC selected from among the plurality of conductive contact patterns DC. A plurality of capacitor structures CAP may be provided, and the plurality of capacitor structures CAP may be respectively connected to corresponding conductive contact patterns DC among the plurality of conductive contact patterns DC. According to embodiments, the etch stop layer 171 may be a silicon nitride layer, and the capacitor insulating layer 173 may be a silicon oxide layer.

Compared to a comparative example in which a first side wall S11 of a channel structure CS includes a line shape extending in one direction, because the first side wall S11 is curved according to embodiments of the present disclosure, the floating body effect in which a threshold voltage of a transistor changes because the body of the transistor fails to have a constant voltage during an operation of a circuit may be reduced, and as a result, a semiconductor device including a vertical channel transistor with improved reliability may be provided.

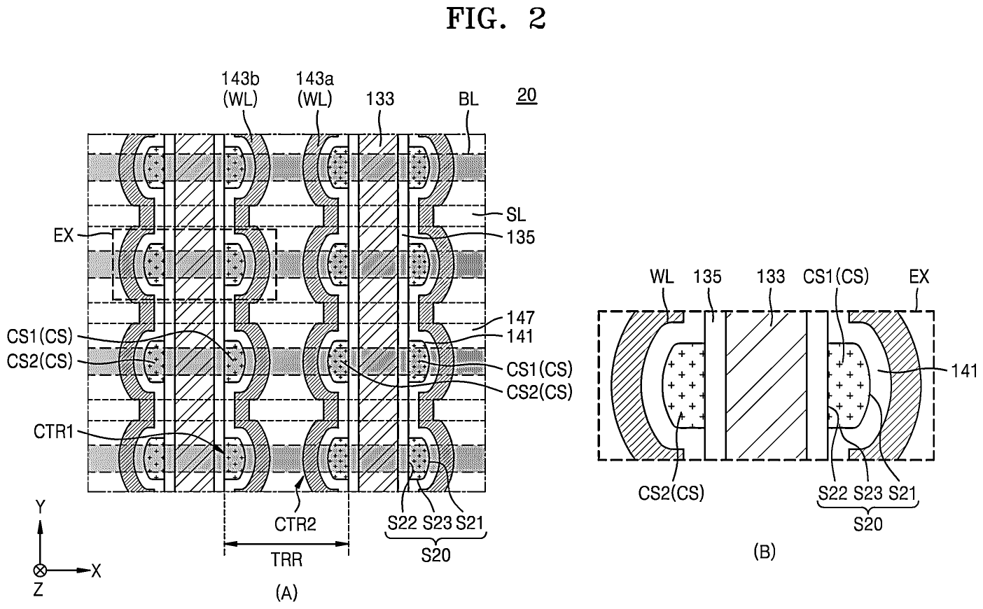

FIG. 2 is a diagram for describing a semiconductor device 20 according to embodiments of the present disclosure. Because the semiconductor device 20 has a substantially similar configuration to the above-described semiconductor device 10, the semiconductor device 20 will be described based on differences from the semiconductor device 10.

Referring to FIG. 2, the semiconductor device 20 may include a substrate 110 (see FIG. 1B), a printed circuit assembly PCA (see FIG. 1B) positioned on the substrate 110, and a plurality of bit lines BL and a plurality of shielding layers SL positioned on the printed circuit assembly PCA. On each bit line (BL), a back gate structure BGS may be positioned.

The back gate structure BGS may include a back gate line 133 and a back gate insulating layer 135 at least partially surrounding a side wall of the back gate line 133. Two or more back gate lines 133 may be provided, and the plurality of back gate lines 133 may be spaced apart from each other in the first horizontal direction (e.g., the X direction). Each of the plurality of back gate lines 133 may extend in the second horizontal direction (e.g., the Y direction). The back gate insulating layer 135 may cover or overlap the side wall of the back gate line 133 and extend conformally along the side wall of the back gate line 133.

A plurality of channel structures CS may be arranged on the back gate insulating layer 135. The plurality of channel structures CS may include a plurality of first channel structures CS1 and a plurality of second channel structures CS2, wherein the plurality of first channel structures CS1 may be spaced apart from the plurality of second channel structures CS2 with the back gate line 133 in between. The plurality of first channel structures CS1 may be symmetrical to the plurality of second channel structures CS2 with the back gate line 133 in between.

Each of the plurality of channel structures CS may include a first side wall S21 facing the back gate insulating layer 135, a second side wall S22 spaced apart from the first side wall S21 and extending on the back gate insulating layer 135, and a third side wall S23 positioned between the first side wall S21 and the second side wall S22 and connecting the first side wall S21 to the second side wall S22, wherein the third side wall S23 may intersect with the second side wall S22.

According to embodiments, the first side wall S21 of the channel structure CS may be curved. For example, the first side wall S21 of the channel structure CS may have a circular-arc shape in a cross-sectional view. The second side wall S22 of the channel structure CS may have a line shape extending along the back gate insulating layer 135. The third side wall S23 of the channel structure CS may have a line shape extending in a direction intersecting with a direction in which the second side wall S22 extends. For example, the second side wall S22 of the channel structure CS may have a line shape extending in the second horizontal direction (e.g., the Y direction), and the third side wall S23 of the channel structure CS may have a line shape extending in the first horizontal direction (e.g., the X direction). According to embodiments, the first side wall S21 of the channel structure CS may be curved, the second side wall S22 of the channel structure CS may be flat, and the third side wall S23 of the channel structure CS may be flat extending in the direction intersecting with the direction in which the second side wall S22 extends. According to embodiments, an entirety of the first side wall S21 of the channel structure CS may be curved. More specifically, the first side wall S21 of the channel structure CS may include no flat surface and the entirety of the first side wall S21 may be curved.

According to embodiments, because the first channel structure CS1 is symmetrical to the second channel structure CS2 with respect to the back gate line 133, the first side wall S21 of the first channel structure CS1 may also be symmetrical to the first side wall S21 of the second channel structure CS2 with respect to the back gate line 133. For example, the first side wall S21 of the first channel structure CS1 may have a circular-arc shape in a cross-sectional view facing one side of the back gate line 133, and in this case, the first side wall S21 of the second channel structure CS2 may have a circular-arc shape in a cross-sectional view facing another side of the back gate line 133 to be symmetrical to the first side wall S21 of the first channel structure CS1.

A gate dielectric layer 141 may be positioned on the plurality of channel structures CS. The gate dielectric layer 141 may cover or overlap side walls of the plurality of channel structures CS, and a portion not covered by the plurality of channel structures CS in a side wall of the back gate insulating layer 135. The gate dielectric layer 141 may extend conformally on the side walls of the plurality of channel structures CS, and the portion not covered by the plurality of channel structures CS in the side wall of the back gate insulating layer 135.

According to embodiments, in the portion covering or overlapping the plurality of channel structures CS in the gate dielectric layer 141, a side wall facing the first side wall S21 may be curved, for example, a circular-arc shape in a cross-sectional view, and a side wall facing the third side wall S32 may have a line shape extending in one direction. A remaining portion of the gate dielectric layer 141 except for the portion covering or overlapping the plurality of channel structures CS may have a line shape. According to embodiments, the side wall facing the first side wall S21 at the portion covering the plurality of channel structures CS in the gate dielectric layer 141 may be curved to correspond to the first side wall S21 of each of the plurality of channel structures CS. According to embodiments, the side wall facing the third side wall S23 at the portion covering or overlapping the plurality of channel structures CS in the gate dielectric layer 141 may be flat to correspond to the third side wall S23 of each of the plurality of channel structures CS.

A word line WL may be positioned on the gate dielectric layer 141. The word line WL may cover or overlap a side wall of the gate dielectric layer 141 and extend along the side wall of the gate dielectric layer 141.

According to embodiments, at a portion surrounding the plurality of channel structures CS in the word line WL, a side wall facing the first side wall S21 may be curved, for example, a circular-arc shape in a cross-sectional view, and a side wall facing the third side wall S23 may have a line shape extending in one direction. Also, a remaining portion of the word line WL except for the portion covering or overlapping the plurality of channel structures CS may have a line shape. According to embodiments, the side wall facing the first side wall S21 at the portion surrounding the plurality of channel structures CS in the word line WL may be curved to correspond to the first side wall S21. The side wall facing the third side wall S23 at the portion surrounding the plurality of channel structures CS in the word line WL may be flat to correspond to the third side wall S23.

In any one back gate line 133 selected from among the plurality of back gate lines 133 and another back gate line 133 being adjacent to the one back gate line 133, a back gate insulating layer 135, a first channel structure CS1, a gate dielectric layer 141, and a word line WL may be arranged on one side, and on another side, a back gate insulating layer 135, a second channel structure CS2, a gate dielectric layer 141, and a word line WL may be arranged.

According to embodiments, because the first channel structures CS1 are symmetrical to the second channel structures CS2 with respect to the back gate line 133, the gate dielectric layer 141 and the word line WL covering or overlapping the first channel structures CS1 may also be symmetrical to the gate dielectric layer 141 and the word line WL covering the second channel structures CS2 with respect to the back gate line 133.

A word line (WL) 143a positioned on one side of any one back gate line 133 selected from among the plurality of back gate lines 133 may be spaced apart from a word line (WL) 143b positioned on another side of another back gate line 133 being adjacent to the one back gate line 133.

An insulating partition wall 145 may extend in the vertical direction (e.g., the Z direction) on an upper surface of the bit line B, and may be positioned between the word line (WL) 143a positioned on the one side of the one back gate line 133 selected from among the plurality of back gate lines 133 and the word line (WL) 143b positioned on the other side of the other back gate line 133 being adjacent to the one back gate line 133.

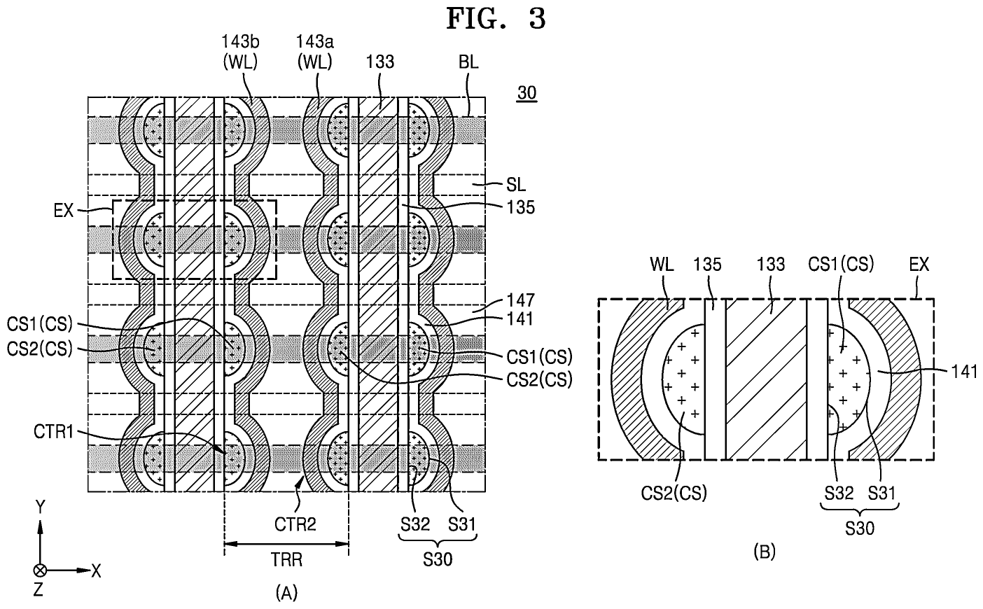

FIG. 3 is a diagram for describing a semiconductor device 30 according to embodiments of the present disclosure. Because the semiconductor device 30 has a substantially similar configuration to the above-described semiconductor device 10, the semiconductor device 30 will be described based on differences from the semiconductor device 10.

Referring to FIG. 3, the semiconductor element 30 may include a substrate 110 (see FIG. 1B), a printed circuit assembly PCA (see FIG. 1B) positioned on the substrate 110, and a plurality of bit lines BL and a plurality of shielding layers SL positioned on the printed circuit assembly PCA. On each bit line BL, a back gate structure BGS may be positioned.

The back gate structure BGS may include a back gate line 133 and a back gate insulating layer 135 at least partially surrounding a side wall of the back gate line 133. Two or more back gate lines 133 may be provided, and the plurality of back gate lines 133 may be spaced apart from each other in the first horizontal direction (e.g., the X direction). Each of the plurality of back gate lines 133 may extend in the second horizontal direction (e.g., the Y direction). The back gate insulating layer 135 may cover or overlap the side wall of the back gate line 133 and extend conformally along the side wall of the back gate line 133.

A plurality of channel structures CS may be positioned on the back gate insulating layer 135. The plurality of channel structures CS may include a plurality of first channel structures CS1 and a plurality of second channel structures CS2, wherein the plurality of first channel structures CS1 may be spaced apart from the second channel structures CS2 with the back gate line 133 in between. The plurality of first channel structure CS1 may be arranged to be symmetrical to the plurality of second channel structure CS2 with the back gate line 133 in between.

Each of the plurality of channel structures CS may include a first side wall S31 facing the back gate insulating layer 135, and a second side wall S32 connected to the first side wall S31 and extending on the back gate insulating layer 135. The first side wall S31 of the channel structure CS may be in contact with an edge of the second side wall S32 and spaced apart from a remaining portion of the second side wall S32 except for the edge of the second side wall S32.

According to embodiments, the first side wall S31 of the channel structure CS may be curved. For example, the first side wall S31 of the channel structure CS may have an elliptical-arc shape in a cross-sectional view. The second side wall S32 of the channel structure CS may have a line shape extending along the back gate insulating layer 135. According to embodiments, the first side wall S31 of the channel structure CS may be curved, and the second side wall S32 of the channel structure CS may be flat. According to embodiments, an entirety of the first side wall S31 of the channel structure CS may be curved. More specifically, the first side wall S31 of the channel structure CS may include no flat portion and the entire of the first side wall S31 may be curved.

According to embodiments, a horizontal width D of the channel structure CS may be constant at different levels in the vertical direction (e.g., the Z direction). For example, a first horizontal width of an upper portion of the channel structure CS may be equal to a second horizontal width of a lower portion of the channel structure CS. According to embodiments, the channel structure CS may have a semi-elliptical pillar shape.

According to embodiments, because the first channel structure CS1 is symmetrical to the second channel structure CS2 with respect to the back gate line 133, a first side wall S31 of the first channel structure CS1 may also be symmetrical to a side wall S31 of the second channel structure CS2 with respect to the back gate line 133. For example, the first side wall S31 of the first channel structure CS1 may have an elliptical-arc shape in a cross-sectional view facing one side of the back gate line 133, and in this case, the first side wall S31 of the second channel structure CS2 may also have an elliptical-arc shape in a cross-sectional view facing another side of the back gate line 133 to be symmetrical to the first side wall S31 of the first channel structure CS1.

A gate dielectric layer film 141 may be positioned on the plurality of channel structures CS. The gate dielectric layer 141 may cover or overlap side walls of the plurality of channel structures CS and a portion not covered or overlapped by the plurality of channel structures CS in a side wall of the back gate insulating layer 135. The gate dielectric layer 141 may extend conformally on the side walls of the plurality of channel structures CS, and the portion not covered or overlapped by the plurality of channel structures CS in the side wall of the back gate insulating layer 135.

According to embodiments, a side wall of a portion covering or overlapping the plurality of channel structures CS in the gate dielectric layer 141 may be curved, for example, an elliptical-arc shape in a cross-sectional view to correspond to the side wall of each of the plurality of channel structures CS. Also, a side wall of a remaining portion of the gate dielectric layer 141, except for the portion covering or overlapping the plurality of channel structures CS, that is, a portion covering or overlapping the back gate insulating layer 135 in the gate dielectric layer 141 may have a line shape. According to embodiments, the side wall of the portion covering or overlapping the plurality of channel structures CS in the gate dielectric layer 141 may be curved, and the side wall of the remaining portion of the gate dielectric layer 141, except for the portion covering or overlapping the plurality of channel structures CS, that is, the portion covering or overlapping the back gate insulating layer 135 in the gate dielectric layer 141 may be flat.

A word line WL may be positioned on the gate dielectric layer 141. The word line WL may cover or overlap a side wall of the gate dielectric layer 141 and extend along the side wall of the gate dielectric layer 141. A portion surrounding the plurality of channel structures CS in the word line WL may be curved, for example, an elliptical-arc shape in a cross-sectional view. Also, a remaining portion of the word line WL except for the portion surrounding the plurality of channel structures CS in the word line WL may have a line shape extending along the side wall of the gate dielectric layer 141. According to embodiments, a side wall of the portion surrounding the plurality of channel structures CS in the word line WL may be curved, and a side wall of the remaining portion of the word line WL except for the portion surrounding the plurality of channel structures CS in the word line WL may be flat.

In any one back gate line 133 selected from among the plurality of back gate lines 133 and another back gate line 133 being adjacent to the one back gate line 133, a back gate insulating layer 135, a first channel structure CS1, a gate dielectric layer 141, and a word line WL may be arranged on one side, and on another side, a back gate insulating layer 135, a second channel structure CS2, a gate dielectric layer 141, and a word line WL may be arranged.

According to embodiments, because the first channel structures CS1 are symmetrical to the second channel structures CS2 with respect to the back gate line 133, the gate dielectric layer 141 and the word line WL covering the first channel structures CS1 may be symmetrical to the gate dielectric layer 141 and the word line WL covering or overlapping the second channel structures CS2 with respect to the back gate line 133.

A word line (WL) 143a positioned on one side of any one back gate line 133 selected from among the plurality of back gate lines 133 may be spaced apart from a word line (WL) 143b positioned on another side of another back gate line 133 being adjacent to the one back gate line 133.

An insulating partition wall 145 may extend in the vertical direction (e.g., the Z direction) on an upper surface of the bit line B, and may be positioned between the word line (WL) 143a positioned on the one side of the one back gate line 133 selected from among the plurality of back gate lines 133 and the word line (WL) 143b positioned on the other side of the other back gate line 133 being adjacent to the one back gate line 133.

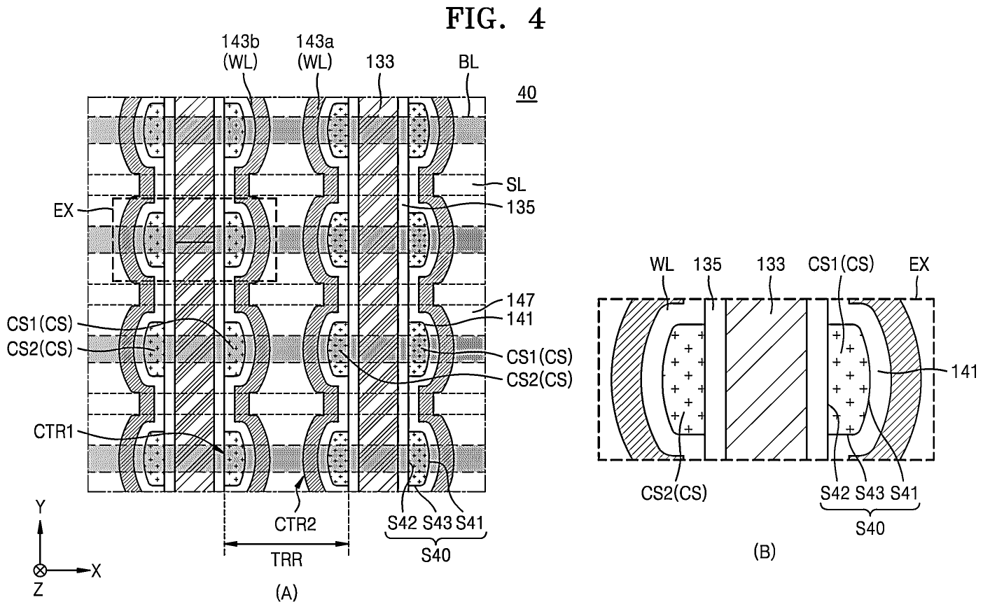

FIG. 4 is a diagram for describing a semiconductor device 40 according to embodiments of the present disclosure. (B) of FIG. 4 is an enlarged view of an area denoted by “EX” in (A) of FIG. 4. Because the semiconductor device 40 has a substantially similar configuration to the above-described semiconductor device 10, the semiconductor device 40 will be described based on differences from the semiconductor device 10.

Referring to FIG. 4, the semiconductor device 40 may include a substrate 110 (see FIG. 1B), a printed circuit assembly PCA (see FIG. 1B) positioned on the substrate 110, and a plurality of bit lines BL and a plurality of shielding layers SL positioned on the printed circuit assembly PCA. On each bit line BL, a back gate structure BGS may be positioned.

The back gate structure BGS may include a back gate line 133 and a back gate insulating layer 135 at least partially surrounding a side wall of the back gate line 133. Two or a plurality of back gate lines 133 may be provided, and the plurality of back gate lines 133 may be spaced apart from each other in the first horizontal direction (e.g., the X direction). Each of the plurality of back gate lines 133 may extend in the second horizontal direction (e.g., the Y direction). The back gate insulating layer 135 may cover or overlap the side wall of the back gate line 133 and extend conformally along the side wall of the back gate line 133.

A plurality of channel structures CS may be positioned on the back gate insulating layer 135. The plurality of channel structures CS may include a plurality of first channel structures CS1 and a plurality of second channel structures CS2, wherein the plurality of first channel structures CS1 may be spaced apart from the plurality of second channel structures CS2 with the back gate line 133 in between. The plurality of first channel structures CS1 may be arranged to be symmetrical to the plurality of second channel structures CS2 with the back gate line 133 in between.

Each of the plurality of channel structures CS may include a first side wall S41 facing the back gate insulating layer 135, a second side wall S42 spaced apart from the first side wall S41 and extending on the back gate insulating layer 135, and a third side wall S43 positioned between the first side wall S41 and the second side wall S42 and connecting the first side wall S41 to the second side wall S42, wherein the third side wall S43 may intersect with the second side wall S42.

According to embodiments, the first side wall S41 of the channel structure CS may be curved. For example, the first side wall S41 of the channel structure CS may have a circular-arc shape in a cross-sectional view. The second side wall S42 of the channel structure CS may have a line shape extending along the back gate insulating layer 135. The third side wall S43 of the channel structure CS may have a line shape extending in a direction intersecting with a direction in which the second side wall S42 extends. For example, the second side wall S42 of the channel structure CS may have a line shape extending in the second horizontal direction (e.g., the Y direction), and the third side wall S43 of the channel structure CS may have a line shape extending in the first horizontal direction (e.g., the X direction). According to embodiments, the first side wall S41 of the channel structure CS may be curved, the second side wall S42 of the channel structure CS may be flat, and the third side wall S43 of the channel structure CS may be flat to intersect with the second side wall S42. According to embodiments, an entirety of the first side wall S41 of the channel structure CS may be curved. More specifically, the first side wall S41 of the channel structure CS may include no flat portion and the entirety of the first side wall S41 may be curved.

According to embodiments, because the first channel structure CS1 is symmetrical to the second channel structure CS2 with respect to the back gate line 133, a first side wall S41 of the first channel structure CS1 may also be symmetrical to a side wall S41 of the second channel structure CS2 with respect to the back gate line 133. For example, the first side wall S41 of the first channel structure CS1 may have a circular-arc shape in a cross-sectional view facing one side of the back gate line 133, and in this case, the first side wall S41 of the second channel structure CS2 may have a circular-arc shape in a cross-sectional view facing another side of the back gate line 133 to be symmetrical to the first side wall S41 of the first channel structure CS1.

A gate dielectric layer film 141 may be positioned on the plurality of channel structures CS. The gate dielectric layer 141 may cover or overlap side walls of the plurality of channel structures CS and a portion not covered or overlapped by the plurality of channel structures CS in a side wall of the back gate insulating layer 135. The gate dielectric layer 141 may extend conformally on the side walls of the plurality of channel structures CS, and the portion not covered or overlapped by the plurality of channel structures CS in the side wall of the back gate insulating layer 135.

According to embodiments, at a portion covering or overlapping the plurality of channel structures CS in the gate dielectric layer 141, a side wall facing the first side wall S41 may be curved, for example, a circular-arc shape in a cross-sectional view and a side wall facing the third side wall S43 may have a line shape extending in one direction. A remaining portion of the gate dielectric layer 141 except for the portion covering or overlapping the plurality of channel structures CS in the gate dielectric layer 141 may have a line shape. According to embodiments, the side wall facing the first side wall S41 at the portion covering or overlapping the plurality of channel structures CS in the gate dielectric layer 141 may be curved to correspond to the first side wall S41 of the plurality of channel structures CS. According to embodiments, a side wall facing the third side wall S43 at the portion covering or overlapping the plurality of channel structures CS in the gate dielectric layer 141 may be flat to correspond to the third side wall S43 of each of the plurality of channel structures CS.

A word line WL may be positioned on the gate dielectric layer 141. The word line WL may cover or overlap a side wall of the gate dielectric layer 141 and extend along the side wall of the gate dielectric layer 141.

According to embodiments, at a portion surrounding the plurality of channel structures CS in the word line WL, a side wall facing the first side wall S41 may be curved, for example, a circular-arc shape in a cross-sectional view and a side wall facing the third side wall S43 may have a line shape extending in one direction. A remaining portion of the word line WL except for the portion surrounding the plurality of channel structures CS in the word line WL may have a line shape. According to embodiments, the side wall facing the first side wall S41 at the portion surrounding the plurality of channel structures CS in the word line WL may be curved to correspond to the first side wall S41. The side wall facing the third side wall S43 at the portion surrounding the plurality of channel structures CS in the word line WL may be flat to correspond to the third side wall S43.

In any one back gate line 133 selected from among the plurality of back gate lines 133 and another back gate line 133 being adjacent to the one back gate line 133, a back gate insulating layer 135, a first channel structure CS1, a gate dielectric layer 141, and a word line WL may be arranged on one side, and on another side, a back gate insulating layer 135, a second channel structure CS2, a gate dielectric layer 141, and a word line WL may be arranged.

According to embodiments, because the first channel structures CS1 are symmetrical to the second channel structures CS2 with respect to the back gate line 133, the gate dielectric layer 141 and the word line WL covering or overlapping the first channel structures CS1 may also be symmetrical to the gate dielectric layer 141 and the word line WL covering or overlapping the second channel structures CS2 with respect to the back gate line 133.

A word line (WL) 143a positioned on one side of any one back gate line 133 selected from among the plurality of back gate lines 133 may be spaced apart from a word line (WL) 143b positioned on another side of another back gate line 133 being adjacent to the one back gate line 133.

An insulating partition wall 145 may extend in the vertical direction (e.g., the Z direction) on an upper surface of the bit line B, and may be positioned between the word line (WL) 143a positioned on the one side of the one back gate line 133 selected from among the plurality of back gate lines 133 and the word line (WL) 143b positioned on the other side of the other back gate line 133 being adjacent to the one back gate line 133.

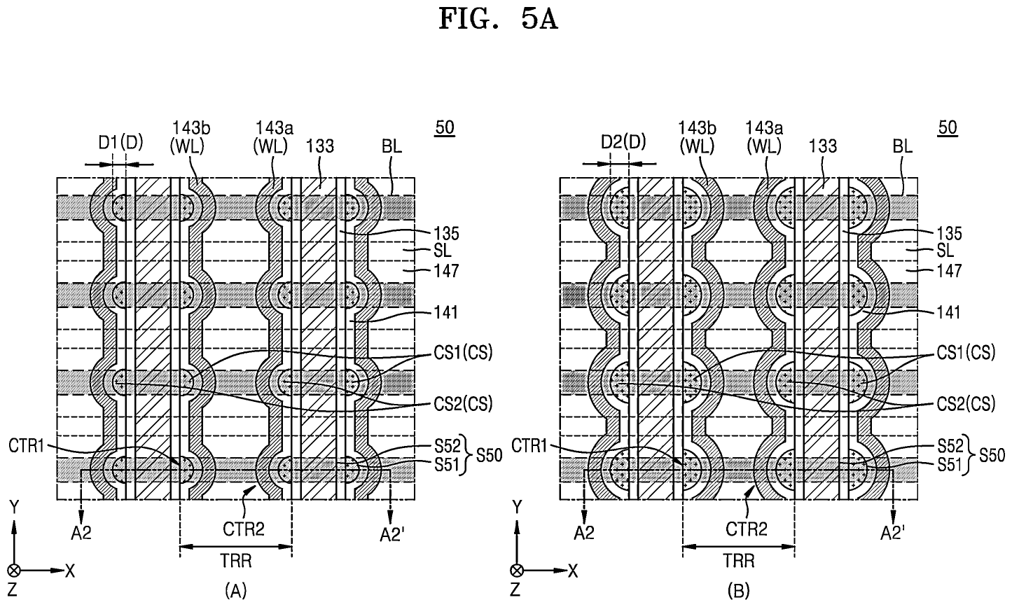

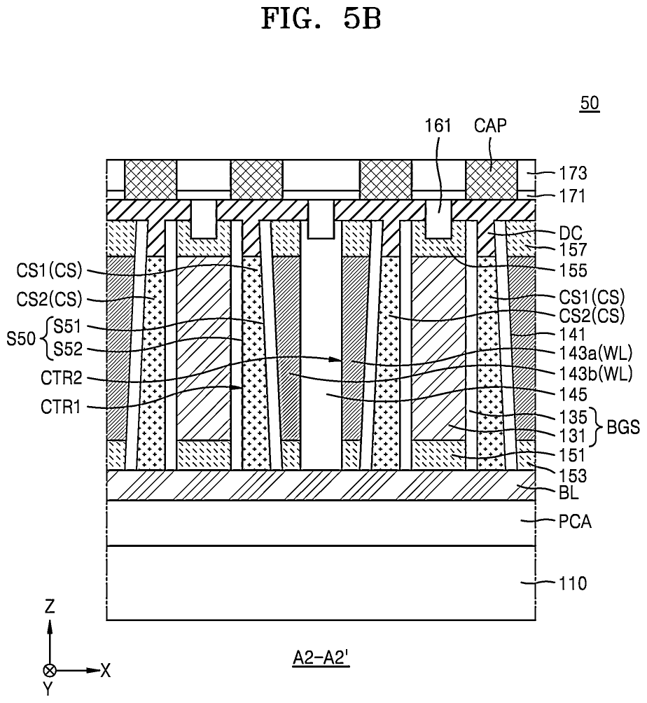

FIG. 5A is a diagram for describing a semiconductor device 50 according to embodiments the present disclosure. FIG. 5B is a cross-sectional view taken along line A2-A2′ of FIG. 5A. (A) of FIG. 5A and (B) of FIG. 5A are top views at different levels in the vertical direction (e.g., the Z direction). More specifically, (A) of FIG. 5A is a top view at an upper level of the semiconductor device 50, and (B) of FIG. 5A is a top view at a lower level of the semiconductor device 50.

Because the semiconductor device 50 has a substantially similar configuration to the above-described semiconductor device 10, the semiconductor device 50 will be described based on differences from the semiconductor device 10.

Referring to (A) and (B) of FIG. 5A, the semiconductor device 50 may include a substrate 110, a printed circuit assembly PCA positioned on the substrate 110, and a plurality of bit lines BL and a plurality of shielding layers SL positioned on the printed circuit assembly PCA.

On each bit line BL, a back gate structure BGS may be positioned. The back gate structure BGS may include a back gate line 133 and a back gate insulating layer 135 at least partially surrounding a side wall of the back gate line 133.

Two or a plurality of back gate lines 133 may be provided, and the plurality of back gate lines 133 may be spaced apart from each other in the first horizontal direction (e.g., the X direction). Each of the plurality of back gate lines 133 may extend in the second horizontal direction (e.g., the Y direction). The back gate insulating layer 135 may cover or overlap the side wall of the back gate line 133 and extend conformally along the side wall of the back gate line 133.

A plurality of channel structures CS may be positioned on the back gate insulating layer 135. According to embodiments, each of the plurality of channel structures CS may be in contact with a bit line BL at the lower surface to be electrically connected to the bit line BL.

Each of the plurality of channel structures CS may include a first side wall S51 facing the back gate insulating layer 135, and a second side wall S52 extending on the back gate insulating layer 135. The first side wall S51 of the channel structure CS may be in contact with an edge of the second side wall S52 and spaced apart from a remaining portion of the second side wall S52 except for the edge of the second side wall S52.

According to embodiments, the first side wall S51 of the channel structure CS may be curved. For example, the first side wall S51 of the channel structure CS may have a circular-arc shape in a cross-sectional view or an elliptical-arc shape in a cross-sectional view. The second side wall S52 of the channel structure CS may have a line shape extending along the back gate insulating layer 135. According to embodiments, the first side wall S51 of the channel structure CS may be curved, and the second side wall S52 of the channel structure CS may be flat. According to embodiments, an entirety of the first side wall S51 of the channel structure CS may be curved. More specifically, the first side wall S51 of the channel structure CS may include no flat portion and the entirety of the first side wall S51 may be curved.

According to embodiments, the channel structure CS may have a semi-circular or semi-elliptical pillar shape. According to embodiments, a horizontal width D of the channel structure CS may change depending on levels in the vertical direction (e.g., the Z direction). For example, a first horizontal width D1 of an upper portion of the channel structure CS may be different from a second horizontal width D2 of a lower portion of the channel structure CS. The horizontal width D of the channel structure CS may increase downward to be greater at a position closer to the bit line BL. According to embodiments, the channel structure CS may have a tapered shape of which a horizontal width decreases from bottom to top.

According to embodiments, because the first channel structure CS1 is symmetrical to the second channel structure CS2 with respect to the back gate line 133, a first side wall S51 of the first channel structure CS1 may also be symmetrical to a first side wall S51 of the second channel structure CS2 with respect to the back gate line 133. For example, the first side wall S51 of the first channel structure CS1 may have a circular-arc or elliptical-arc shape in a cross-sectional view facing one side of the back gate line 133, and in this case, the first side wall S51 of the second channel structure CS2 may also have a circular-arc or elliptical-arc shape in a cross-sectional view facing another side of the back gate line 133 to be symmetrical to the first side wall S51 of the first channel structure CS1.

A gate dielectric layer film 141 may be positioned on the plurality of channel structures CS. The gate dielectric layer 141 may cover or overlap side walls of the plurality of channel structures CS, and a portion not covered or overlapped by the plurality of channel structures CS in a side wall of the back gate insulating layer 135. The gate dielectric layer 141 may extend conformally on the side walls of the plurality of channel structures CS, and the portion not covered or overlapped by the plurality of channel structures CS in the side wall of the back gate insulating layer 135.

A word line WL may be positioned on the gate dielectric layer 141. An insulating partition wall 145 may insulate the word line (WL) 143a positioned on the one side of the one back gate line 133 selected from among the plurality of back gate lines 133 from the word line (WL) 143b positioned on the other side of the other back gate line 133 being adjacent to the one back gate line 133. The insulating partition wall 145 may extend in the vertical direction (e.g., the Z direction) on an upper surface of the bit line B, and may be positioned between the word line (WL) 143a positioned on the one side of the one back gate line 133 selected from among the plurality of back gate lines 133 and the word line (WL) 143b positioned on the other side of the other back gate line 133 being adjacent to the one back gate line 133. The word line WL may be positioned between the gate dielectric layer 141 and the insulating partition wall 145 to at least partially fill or be in a gap between the gate dielectric layer 141 and the insulating partition wall 145.

A lower back gate capping layer 151 may be positioned at a lower portion of the back gate line 133. The lower back gate capping layer 151 may be positioned between the back gate line 133 and the bit line BL to prevent the back gate line 133 from contacting the bit line BL. An upper back gate capping layer 155 may be positioned at an upper portion of the back gate line 133. The upper back gate capping layer 155 may be positioned between the back gate line 133 and a conductive contact pattern DC positioned above the back gate line 133 to prevent the back gate line 133 from contacting the conductive contact pattern DC.

At a lower portion of the word line WL, a lower word line capping layer 153 may be positioned. The lower back gate capping layer 151 may be positioned between the word line WL and the bit line BL to prevent the word line WL from contacting the bit line BL. At an upper portion of the word line WL, an upper word line capping layer 157 may be positioned. The upper word line capping layer 157 may be positioned between the word line WL and the conductive contact pattern DC positioned above the word line WL to prevent the word line WL from contacting the conductive contact pattern DC. The lower word line capping layer 153 and the upper word line capping layer 157 may be positioned between the gate dielectric layer 141 and the insulating partition wall 145.

A plurality of conductive contact patterns DC may be positioned above the plurality of channel structures CS. Each of the plurality of conductive contact patterns DC may be connected to any one channel structure CS selected from among the plurality of channel structures CS. The plurality of conductive contact patterns DC may be spaced apart from each other by a separation insulation pattern 161.

The semiconductor device 50 may further include a capacitor structure CAP connected to any one of the conductive contact patterns DC. An etch stop layer 171 and a capacitor insulating layer 173 may be applied in order on the plurality of conductive contact patterns DC and the separation insulation pattern 161, and the capacitor structure CAP may penetrate or extend into the capacitor insulating layer 173 and the etch stop layer 171 in the vertical direction (e.g., the Z direction) to be connected to any one conductive contact pattern DC selected from among the plurality of conductive contact patterns DC.

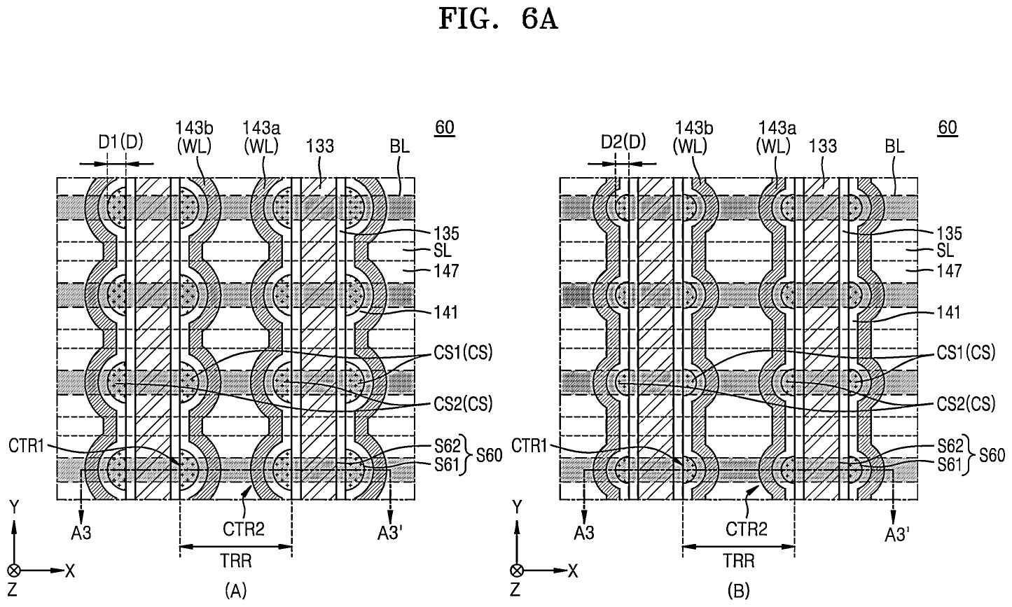

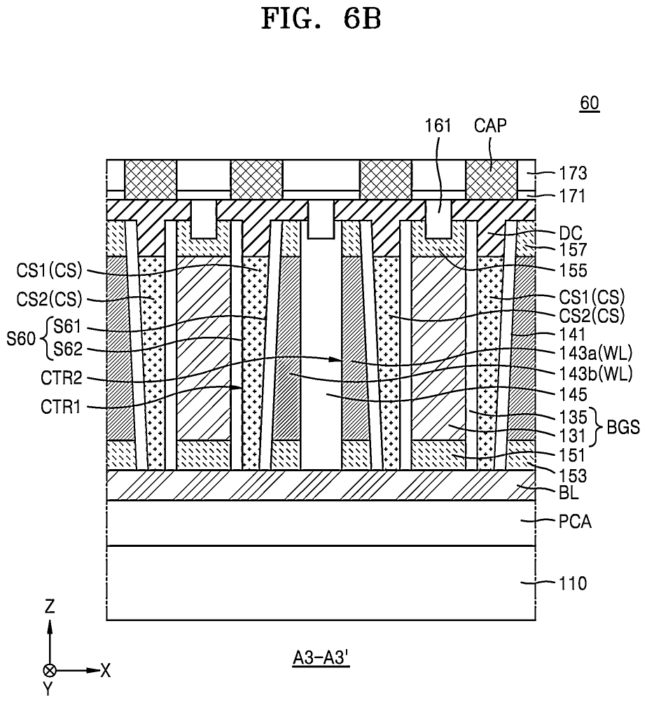

FIG. 6A is a diagram for describing a semiconductor device 60 according to embodiments the present disclosure. FIG. 6B is a cross-sectional view taken along line A3-A3′ of FIG. 6A. (A) of FIG. 6A and (B) of FIG. 6A are top views at different levels in the vertical direction (e.g., the Z direction). More specifically, (A) of FIG. 6A is a top view at an upper level of the semiconductor device 60, and (B) of FIG. 6A is a top view at a lower level of the semiconductor device 60.

Referring to (A) and (B) of FIG. 6A, the semiconductor device 60 may include a substrate 110, a printed circuit assembly PCA positioned on the substrate 110, and a plurality of bit lines BL and a plurality of shielding layers SL positioned on the printed circuit assembly PCA.

On each bit line BL, a back gate structure BGS may be positioned. The back gate structure BGS may include a back gate line 133 and a back gate insulating layer 135 at least partially surrounding a side wall of the back gate line 133.

Two or a plurality of back gate lines 133 may be provided, and the plurality of back gate lines 133 may be spaced apart from each other in the first horizontal direction (e.g., the X direction). Each of the plurality of back gate lines 133 may extend in the second horizontal direction (e.g., the Y direction). The back gate insulating layer 135 may cover or overlap the side wall of the back gate line 133 and extend conformally along the side wall of the back gate line 133.

A plurality of channel structures CS may be positioned on the back gate insulating layer 135. According to embodiments, each of the plurality of channel structures CS may be in contact with a bit line BL at the lower surface to be electrically connected to the bit line BL.

Each of the plurality of channel structures CS may include a first side wall S61 facing the back gate insulating layer 135, and a second side wall S62 extending on the back gate insulating layer 135. The first side wall S61 of the channel structure CS may be in contact with an edge of the second side wall S62 and spaced apart from a remaining portion of the second side wall S62 except for the edge of the second side wall S62.

According to embodiments, the first side wall S61 of the channel structure CS may be curved. For example, the first side wall S61 of the channel structure CS may have a circular-arc or elliptical-arc shape in a cross-sectional view. The second side wall S62 of the channel structure CS may have a line shape extending along the back gate insulating layer 135. According to embodiments, the first side wall S61 of the channel structure CS may be curved, and the second side wall S62 of the channel structure CS may be flat. According to embodiments, an entirety of the first side wall S61 of the channel structure CS may be curved. More specifically, the first side wall S61 of the channel structure CS may include no flat portion and the entirety of the first side wall S61 may be curved. According to embodiments, the channel structure CS may have a semi-circular or semi-elliptical pillar shape.

According to embodiments, a horizontal width D of the channel structure CS may change depending on levels in the vertical direction (e.g., the Z direction). For example, a first horizontal width D1 of an upper portion of the channel structure CS may be different from a second horizontal width D2 of a lower portion of the channel structure CS. The horizontal width D of the channel structure CS may decrease downward to be smaller at a position closer to the bit line BL (e.g., the horizontal width D decreases as a respective distance between each of the plurality of channel structures CS and the bit line BL decreases). According to embodiments, the channel structure CS may have a tapered shape of which a horizontal width decreases from top to bottom.

According to embodiments, because the first channel structure CS1 is symmetrical to the second channel structure CS2 with respect to the back gate line 133, a first side wall S61 of the first channel structure CS1 may also be symmetrical to a first side wall S61 of the second channel structure CS2 with respect to the back gate line 133. For example, the first side wall S61 of the first channel structure CS1 may have a circular-arc or elliptical-arc shape in a cross-sectional view facing one side of the back gate line 133, and in this case, the first side wall S61 of the second channel structure CS2 may also have a circular-arc or elliptical-arc shape in a cross-sectional view facing another side of the back gate line 133 to be symmetrical to the first side wall S61 of the first channel structure CS1.

A gate dielectric layer film 141 may be positioned on the plurality of channel structures CS. The gate dielectric layer 141 may cover or overlap side walls of the plurality of channel structures CS, and a portion not covered or overlapped by the plurality of channel structures CS in a side wall of the back gate insulating layer 135. The gate dielectric layer 141 may extend conformally on the side walls of the plurality of channel structures CS, and the portion not covered or overlapped by the plurality of channel structures CS in the side wall of the back gate insulating layer 135.

A word line WL may be positioned on the gate dielectric layer 141. An insulating partition wall 145 may insulate a word line (WL) 143a positioned on one side of one back gate line 133 selected from among the plurality of back gate lines 133 from a word line (WL) 143b positioned on another side of another back gate line 133 being adjacent to the one back gate line 133. The insulating partition wall 145 may extend in the vertical direction (e.g., the Z direction) on an upper surface of the bit line B, and may be positioned between the word line (WL) 143a positioned on the one side of the one back gate line 133 selected from among the plurality of back gate lines 133 and the word line (WL) 143b positioned on the other side of the other back gate line 133 being adjacent to the one back gate line 133. The word line WL may be positioned between the gate dielectric layer 141 and the insulating partition wall 145 to at least partially fill or be in a gap between the gate dielectric layer 141 and the insulating partition wall 145.

A lower back gate capping layer 151 may be positioned at a lower portion of the back gate line 133. The lower back gate capping layers 151 may be positioned between the back gate line 133 and the bit line BL to prevent the back gate line 133 from contacting the bit line BL. An upper back gate capping layer 155 may be positioned at an upper portion of each back gate line 133. The upper back gate capping layer 155 may be positioned between the back gate line 133 and a conductive contact pattern DC positioned above the back gate line 133 to prevent the back gate line 133 from contacting the conductive contact pattern DC.

A lower word line capping layer 153 may be positioned at a lower portion of the word line WL. The lower back gate capping layer 153 may be positioned between the word line WL and the bit line BL to prevent the word line WL from contacting the bit line BL. An upper word line capping layer 157 may be positioned at an upper portion of the word line WL. The upper word line capping layer 157 may be positioned between the word line WL and the conductive contact pattern DC positioned above the word line WL to prevent the word line WL from contacting the conductive contact pattern DC. The lower word line capping layer 153 and the upper word line capping layer 157 may be positioned between the gate dielectric layer 141 and the insulating partition wall 145.

A plurality of conductive contact patterns DC may be positioned above the plurality of channel structures CS. Each of the plurality of conductive contact patterns DC may be connected to any one channel structure CS selected from among the plurality of channel structures CS. The plurality of conductive contact patterns DC may be spaced apart from each other by a separation insulation pattern 161.

The semiconductor device 60 may further include a capacitor structure CAP connected to one of the plurality of conductive contact patterns DC. An etch stop layer 171 and a capacitor insulating layer 173 may be applied in order on the plurality of conductive contact patterns DC and the separation insulation pattern 161, and the capacitor structure CAP may penetrate the capacitor insulating layer 173 and the etch stop layer 171 in the vertical direction (e.g., the Z direction) to be connected to any one conductive contact pattern DC selected from among the plurality of conductive contact patterns DC.

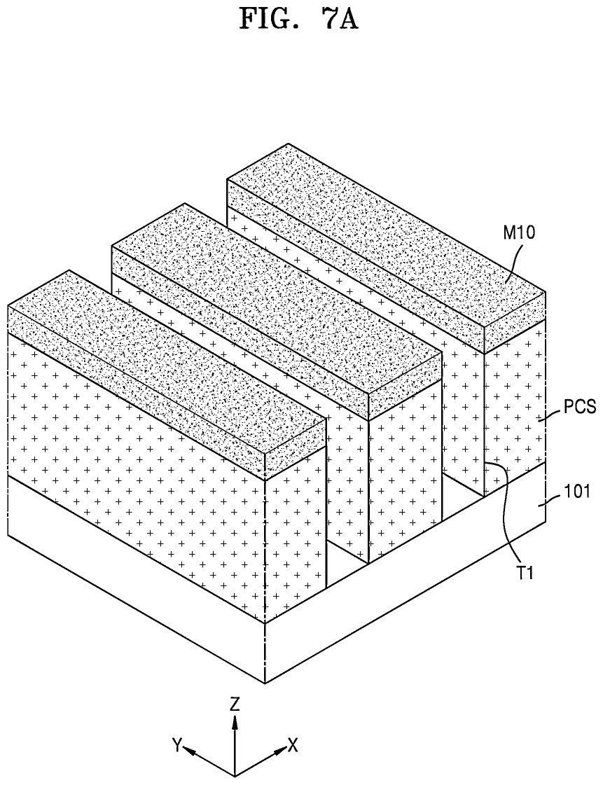

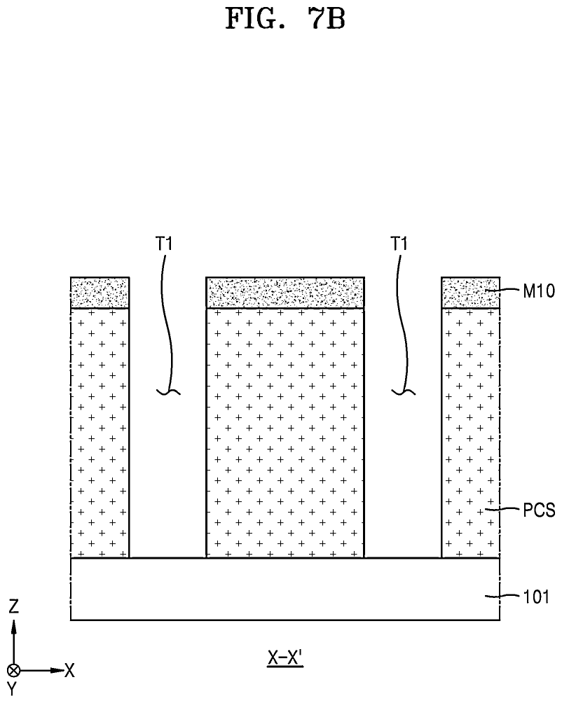

FIGS. 7A, 7B, 8A, 8B, 9A, 9B, 10, 11, 12A, 12B, 13A, 13B, and 14 to 18 show processes in sequence to describe a method for manufacturing a semiconductor device 10 according to embodiments of the present disclosure.

Referring to FIGS. 7A and 7B, a preliminary channel structure PCS may be formed on a sacrificial substrate 101. The preliminary channel structure PCS may include a semiconductor material or an oxide semiconductor material. The semiconductor material may include, for example, single-crystal silicon or polysilicon. The oxide semiconductor material may include at least one metal element selected from among, for example, In, Ga, and Zn, and may include at least one among, for example, IGZO, SN-doped IGZO, W-doped IGZO, or IZO. Also, IGZO may include at least one among single crystalline IGZO, polycrystalline IGZO, spinel IGZO, or CAAC IGZO.

Thereafter, a channel mask M10 including a plurality of openings may be formed on the preliminary channel structure PCS, and a patterning process of removing a portion of the preliminary channel structure PCS through the plurality of openings may be performed to form a plurality of trenches T1 penetrating or extending into the preliminary channel structure PCS. The plurality of trenches T1 may be spaced apart from each other in the first horizontal direction (e.g., the X direction) and extend in the second horizontal direction (e.g., the Y direction). An upper surface of the sacrificial substrate 101 may be exposed through bottoms of the plurality of trenches T1.

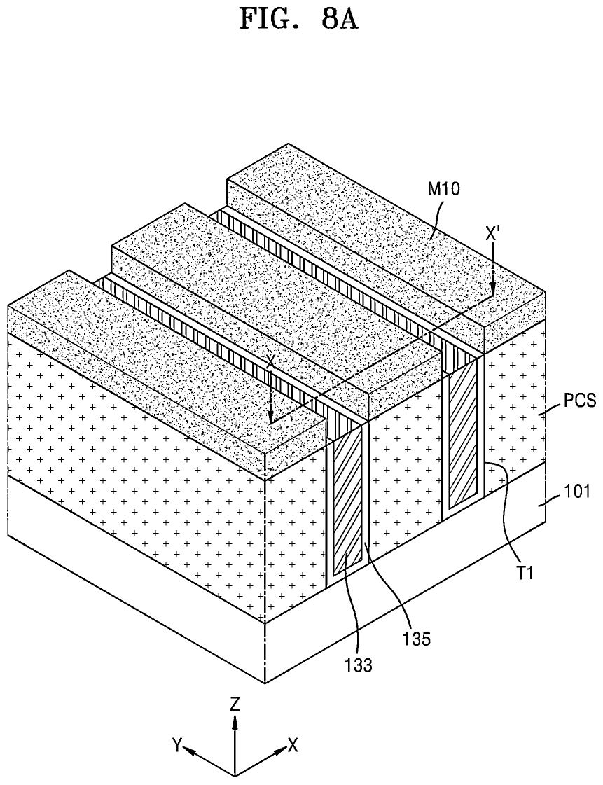

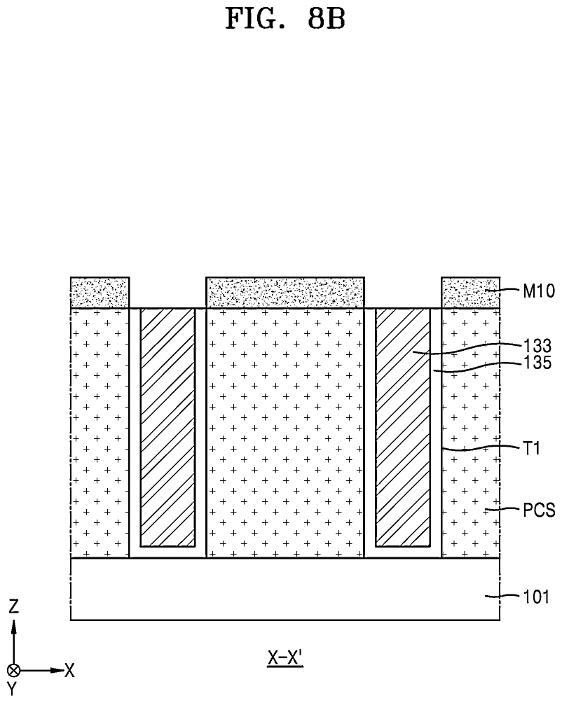

Referring to FIGS. 8A and 8B, a back gate line 133 and a back gate insulating layer 135 may be formed to fill or be in each of the plurality of trenches T1. The back gate insulating layer 135 may extend conformally along an inner wall of the trench T1 in such a way as not to fill or be in an entirety of the trench T1. The back gate line 133 may fill a space not filled with or including the back gate insulating layer 135 in the trench T1.

According to embodiments, the back gate line 133 may include a metal (for example, Mo, Ru, W), a metal nitride (for example, TiN, TaN, WN) or a conductive material (for example, metal silicide).

According to embodiments, the back gate insulating layer 135 may include an oxide such as silicon oxide. Alternatively, the back gate insulating layer 135 may include a metal oxide having a high dielectric constant, such as hafnium oxide and zirconium oxide, and have a multilayer structure including a first layer being in contact with the side wall of the back gate line 133 and a second layer including a silicon oxide and being in contact with a side wall of the first layer.

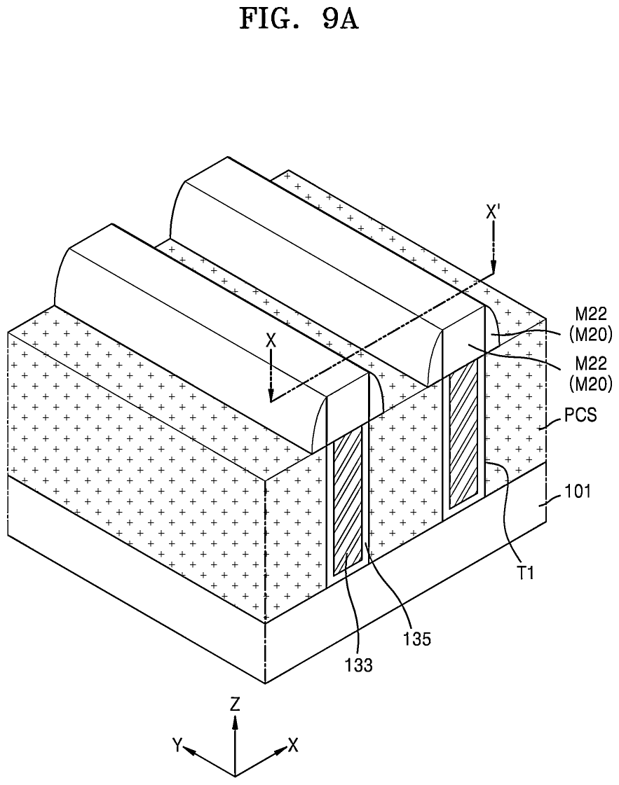

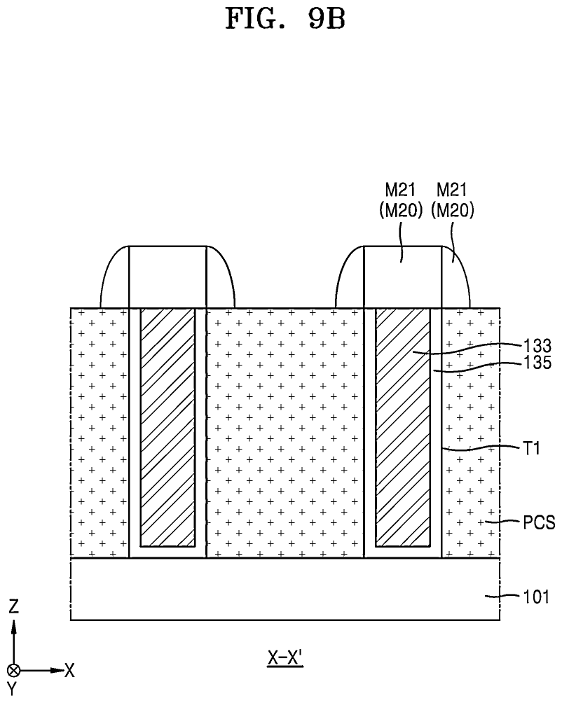

Referring to FIGS. 9A and 9B, a second mask M20 may be formed on the preliminary channel structure PCS. The second mask M20 may include a first portion M21 extending with a long length in the second horizontal direction (e.g., the Y direction), and a second portion M22 extending with a short length in the first horizontal direction (e.g., the X direction) from the first portion M21. The first portion M21 of the second mask M20 can cover or overlap upper surfaces of the back gate line 133 and the back gate insulating layer 135, and the second portion M22 may cover or overlap a portion of an upper surface of the preliminary channel structure PCS. According to embodiments, the second portion M22 may include an inclined surface extending from an upper surface of the first portion M21 to the upper surface of the preliminary channel structure PCS.

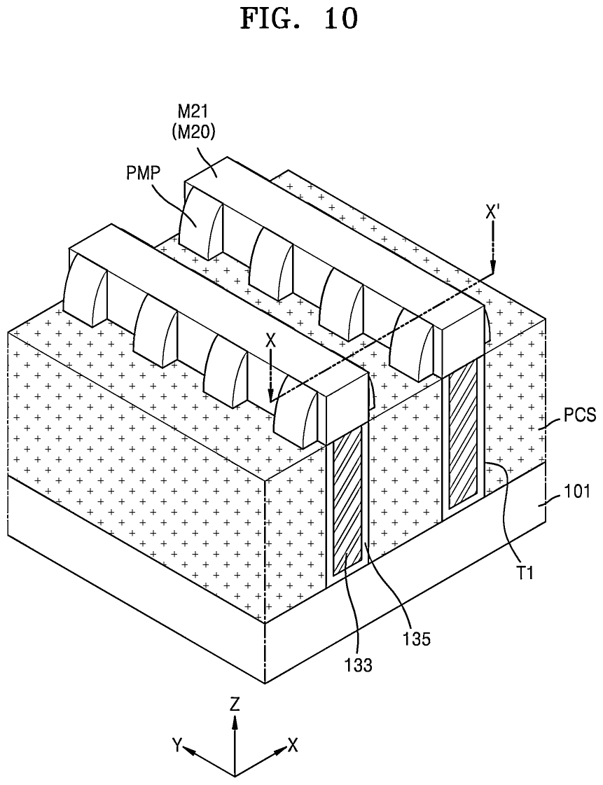

Referring to FIG. 10, a part of the second portion M22 of the second mask M20 of FIGS. 9A and 9B may be etched to form a plurality of preliminary mask patterns PMP spaced apart from each other in the second horizontal direction (e.g., the Y direction). The plurality of preliminary mask patterns PMP may cover a portion of the upper surface of the preliminary channel structure PCS. The plurality of preliminary mask patterns PMP may be used to form a plurality of channel structures CS, which will be described below. According to embodiments, each of the plurality of preliminary mask patterns PMP may include an inclined surface extending from the upper surface of the first portion M21 of the second mask M20 to the upper surface of the preliminary channel structure PCS. A lower surface of each of the plurality of preliminary mask patterns PMP may have a shape including angled corners, for example, a quadrangular shape.

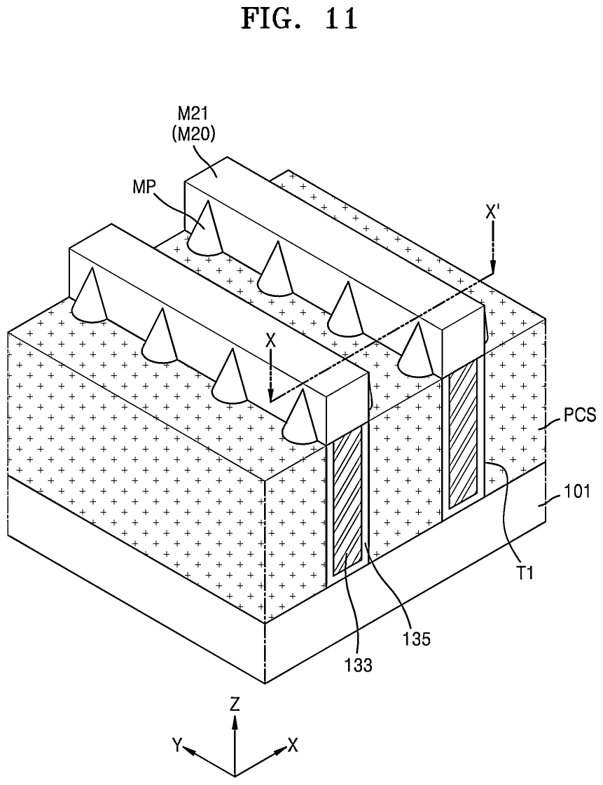

Referring to FIG. 11, a portion of the plurality of preliminary mask patterns PMP of FIG. 10 may be etched to form a plurality of mask patterns MP. An etching process for forming the plurality of mask patterns MP may be a 3Dimensional (3D) etching process, and according to embodiments, the 3D etching process may include an oxidation process and a wet etch process.

The plurality of mask patterns PMP may cover or overlap a portion of the upper surface of each preliminary channel structure PCS. According to embodiments, each of the plurality of mask patterns MP may include an inclined surface extending from the upper surface or side wall of the first portion M21 of the second mask M20 to the upper surface of the preliminary channel structure PCS. According to embodiments, a side wall of each of the plurality of mask patterns MP may be curved. For example, the side wall of each of the plurality of mask patterns MP may include a circular-arc shape in a cross-sectional view. According to embodiments, the side wall of each of the plurality of mask patterns MP may include a curved surface, and each of the plurality of mask patterns MP may be formed in a cone shape. A lower surface of each of the plurality of mask patterns MP may have a semi-circular shape. According to embodiments, a horizontal width of each of the plurality of mask patterns MP may range from 5 nanometers to 10 nanometers.

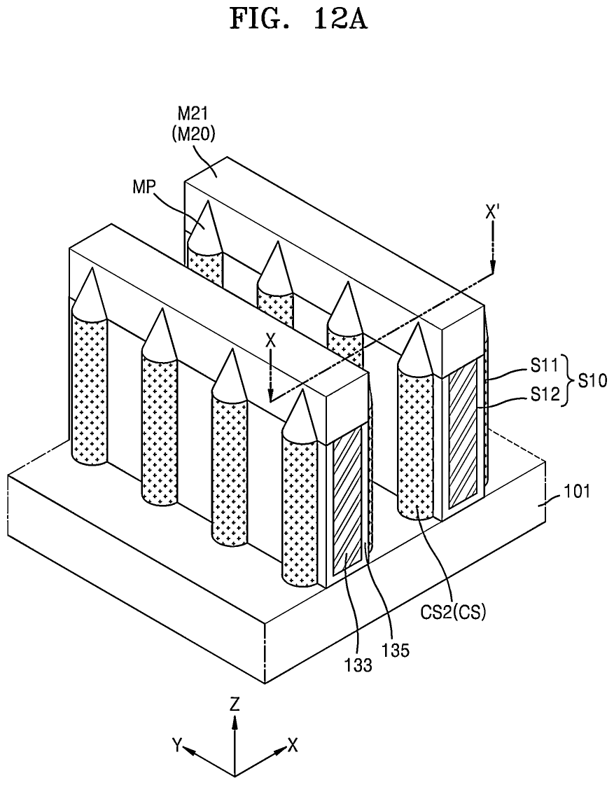

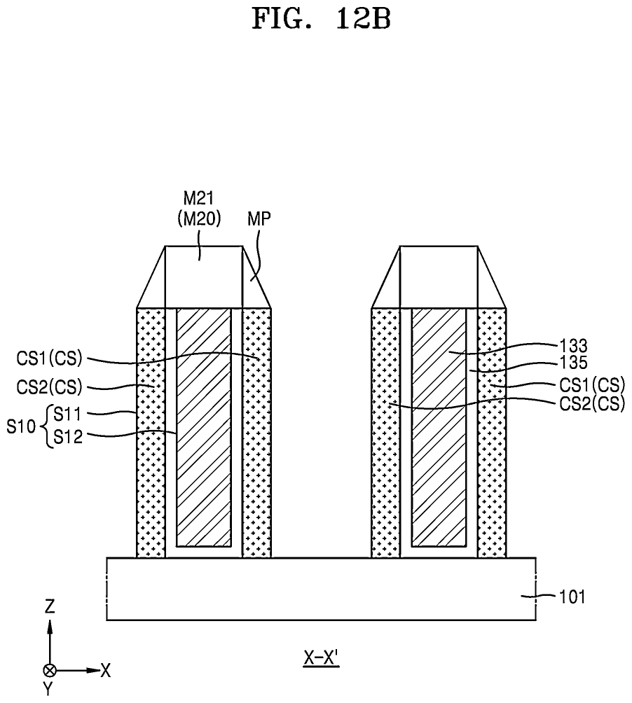

Referring to FIGS. 12A and 12B, a portion of the preliminary channel structure PCS may be etched by using the plurality of mask patterns MP of FIG. 11 as etching masks to form a plurality of channel structures CS. The plurality of channel structures CS may include a plurality of first channel structures CS1 and a plurality of second channel structures CS2, wherein the plurality of first channel structures CS1 may be spaced apart from the plurality of second channel structures CS2 with the back gate line 133 in between. The plurality of first channel structures CS1 may face one side wall of the back gate line 133, and the plurality of second channel structures CS2 may face another side wall of the back gate line 133. The plurality of first channel structures CS1 may be arranged to be spaced apart from each other along the one side wall of the back gate line 133, and the plurality of second channel structures CS2 may be arranged to be spaced apart from each other along the other side wall of the back gate line 133. The plurality of first channel structures CS1 may be arranged to be symmetrical to the plurality of second channel structures CS2 with the back gate line 133 in between.

According to embodiments, each of the plurality of channel structures CS may have a semi-circular shape, like the lower surface of each of the plurality of mask patterns MP. Because a side wall of each of the plurality of mask patterns MP is curved, for example, a circular-arc shape in a cross-sectional view, a first side wall S11 of the channel structure CS may be curved, for example, a circular-arc shape in a cross-sectional view. A second side wall S12 of the channel structure CS may have a line shape extending along the back gate insulating layer 135. According to embodiments, the first side wall S11 of the channel structure CS may be curved, and the second side wall S12 of the channel structure CS may be flat.

According to embodiments, a horizontal width D of the channel structure CS may be constant at different levels in the vertical direction (e.g., the Z direction). For example, a first horizontal width of an upper portion of the channel structure CS may be equal to a second horizontal width of a lower portion of the channel structure CS. According to embodiments, the channel structure CS may have a semi-circular pillar shape. According to embodiments, the horizontal width of the channel structure CS may range from 5 nanometers to 10 nanometers.

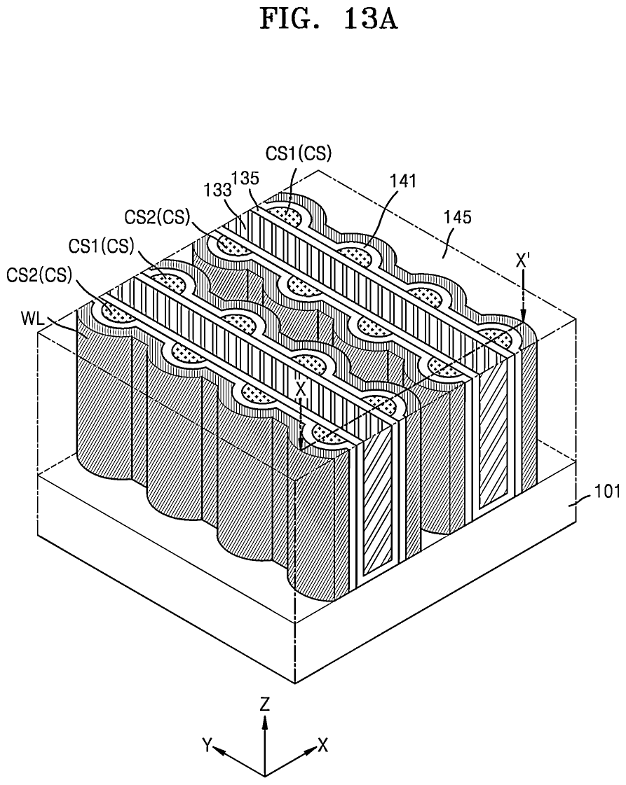

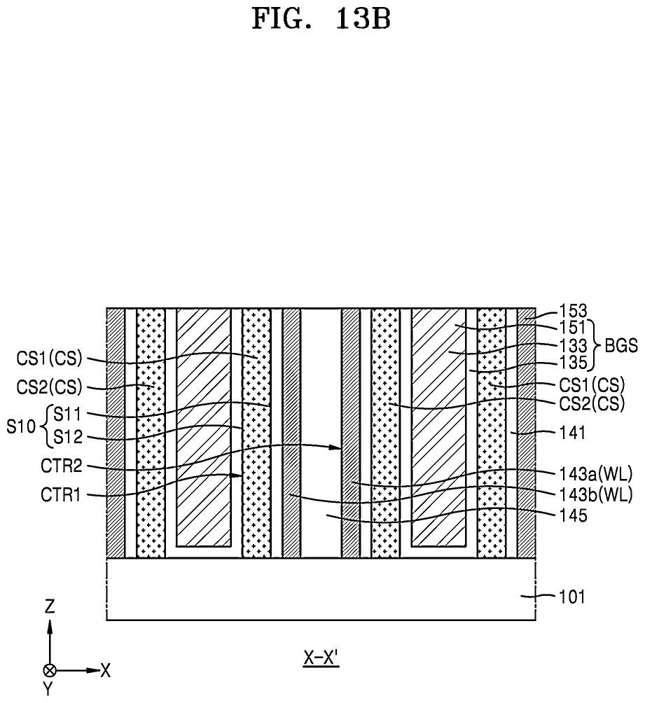

Referring to FIGS. 13A and 13B, the mask patterns MP of FIG. 12 may be removed, and a gate dielectric layer 141 covering or overlapping the side walls of the plurality of channel structures CS, and a portion not covered or overlapped by the plurality of channel structures CS in the side wall of the back gate insulating layer 135 may be formed. The gate dielectric layer 141 may extend conformally on the side walls of the plurality of channel structures CS, and the portion not covered or overlapped by the plurality of channel structures CS in the side wall of the back gate insulating layer 135. According to embodiments, the gate dielectric layer 141 may be formed of at least one selected from among a ferroelectric material and a high-k dielectric material having a greater dielectric constant than a silicon oxide.

Thereafter, a word line WL covering or overlapping a side wall of the gate dielectric layer 141 may be formed. According to embodiments, the word line WL may include Ti, TiN, Ta, TaN, W, WN, TiSiN, WSiN, polysilicon or a combination thereof.

At a portion covering or overlapping each of the plurality of channel structures CS in the gate dielectric layer 141, a side wall of the gate dielectric layer 141 may be curved, like the side wall of each of the plurality of channel structures CS. Also, at a portion covering or overlapping each of the plurality of channel structures CS in the word line WL, a side wall of the word line WL may be curved, like the side wall of each of the plurality of channel structures CS.

An insulating partition wall 145 for insulating between any word line WL from among the plurality of word lines WL and another word line WL being adjacent to the word line WL may be formed between the one word line WL and the other word line WL. According to embodiments, the insulating partition wall 145 may include a silicon oxide, a silicon nitride, or a combination thereof.

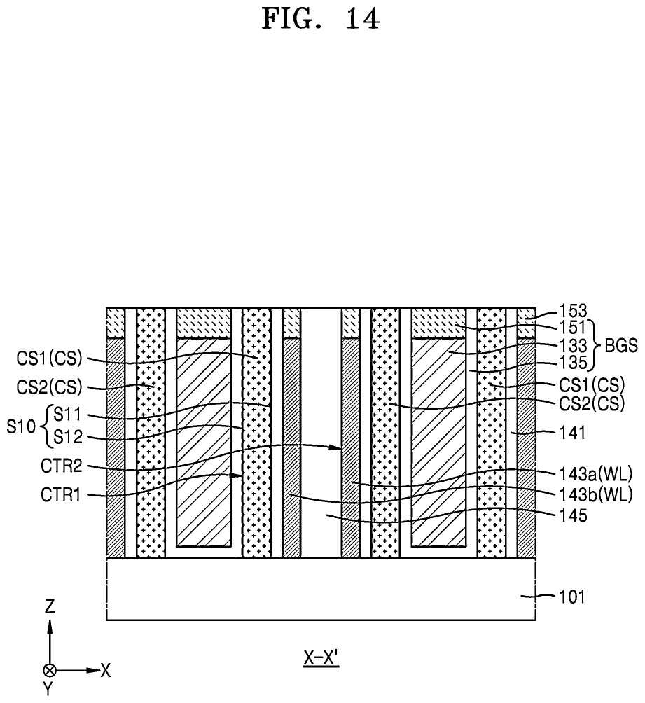

Referring to FIG. 14, a part of an upper portion of the back gate line 133 and a part of an upper portion of the word line WL may be removed to form a lower back gate capping layer 151 and a lower word line capping layer 153. According to embodiments, the lower back gate capping layer 151 and the lower word line capping layer 153 may be formed simultaneously. According to embodiments, the lower back gate capping layer 151 and the lower word line capping layer 153 may include the same material. For example, the lower back gate capping layer 151 and the lower word line capping layer 153 may include a silicon oxide, a silicon nitride, or a combination thereof.

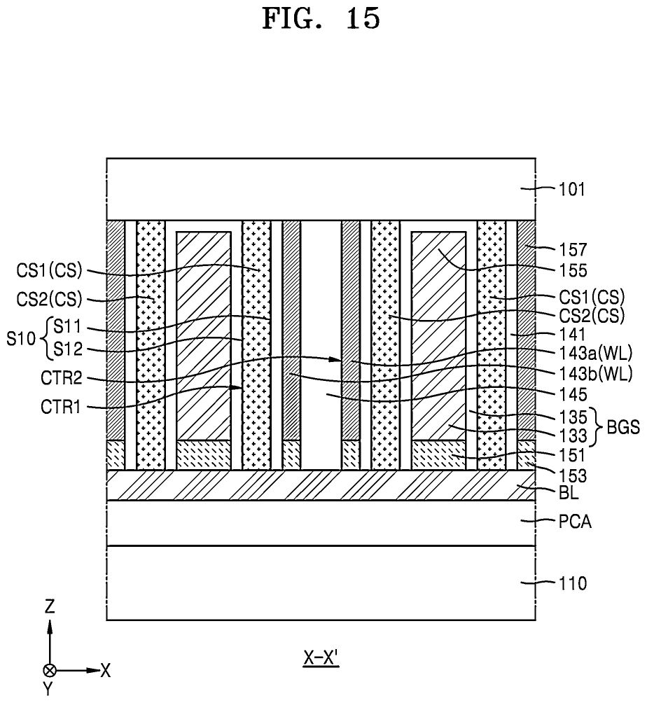

Referring to FIG. 15, a substrate 110 on which a printed circuit assembly PCA and a bit line BL are applied may be prepared. A resultant structure shown in FIG. 14 may be reversed, and then, a process of bonding the resultant structure shown in FIG. 14 with the substrate 110 on which the printed circuit assembly PCA and the bit line BL are applied may be performed.

By the bonding process, the plurality of channel structures CS may be in contact with an upper surface of the bit line BL to be electrically connected to the bit line BL.

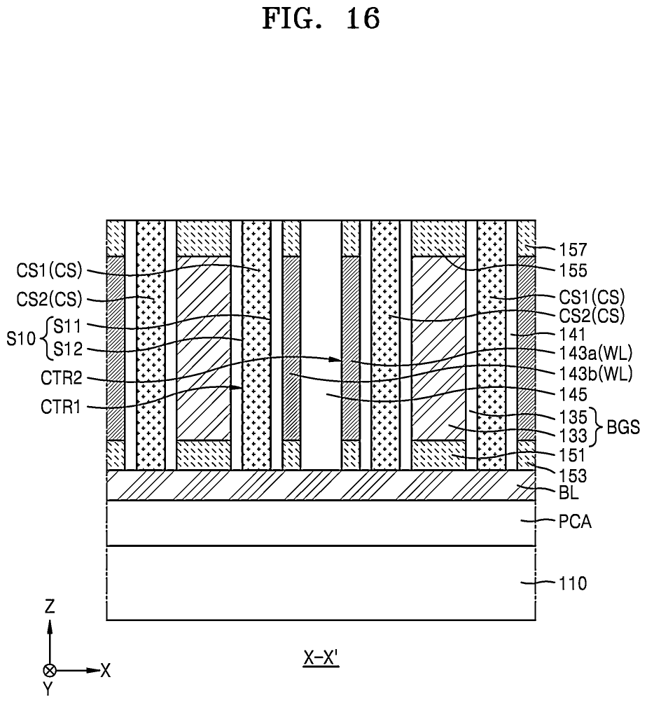

Referring to FIG. 16, the sacrificial substrate 101 may be removed from a resultant structure shown in FIG. 15, and then, a process of polishing an upper surface of the resultant structure from which the sacrificial substrate 101 has been removed may be performed. The polishing process may include a grinding process. Through the polishing process, a portion of the back gate insulating layer 135 overlapping with the back gate line 133 in the vertical direction (e.g., the Z direction) may be removed, and thus, an upper surface of the back gate line 133 may be exposed.

Thereafter, a part of the upper portion of the back gate line 133 and a part of the upper portion of the word line WL may be removed to form an upper back gate capping layer 155 and an upper word line capping layer 157. According to embodiments, the upper back gate capping layer 155 and the upper word line capping layer 157 may be formed simultaneously. According to embodiments, the upper back gate capping layer 155 and the upper word line capping layer 157 may include the same material. For example, the upper back gate capping layer 155 and the upper word line capping layer 157 may include a silicon oxide, a silicon nitride, or a combination thereof.

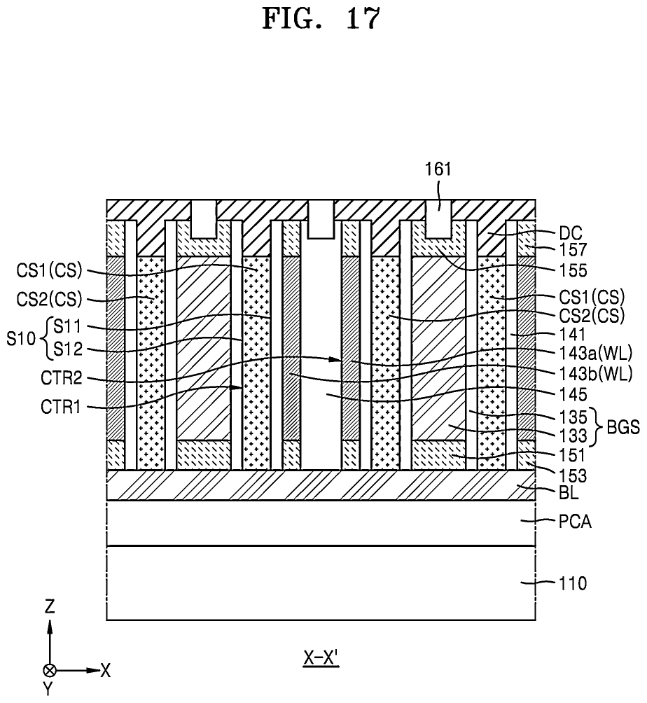

Referring to FIG. 17, a recess process may be performed on the upper surfaces of the channel structures CS to remove a part of the upper portions of the channel structures CS. Through the recess process, the upper surfaces of the channel structures CS may be positioned at a lower level than the upper surfaces of the back gate insulating layer 135 and the gate dielectric layer 141.

Then, a conductive layer for forming a plurality of conductive contact patterns DC may be formed on an upper surface of a resultant structure on which the recess process has been performed. The conductive layer may include Ti, TiN, Ta, TaN, W, WN, TiSiN, WSIN, polysilicon or a combination thereof. A mask (not shown) may be formed on the conductive layer. Then, a portion of the conductive layer may be removed and a remaining portion of the conductive layer may form the plurality of conductive contact patterns DC. A separation insulation pattern 161 may be formed in a region from which the portion of the conductive layer has been removed. The separation insulation pattern 161 may include a silicon oxide, a silicon nitride, or a combination thereof.

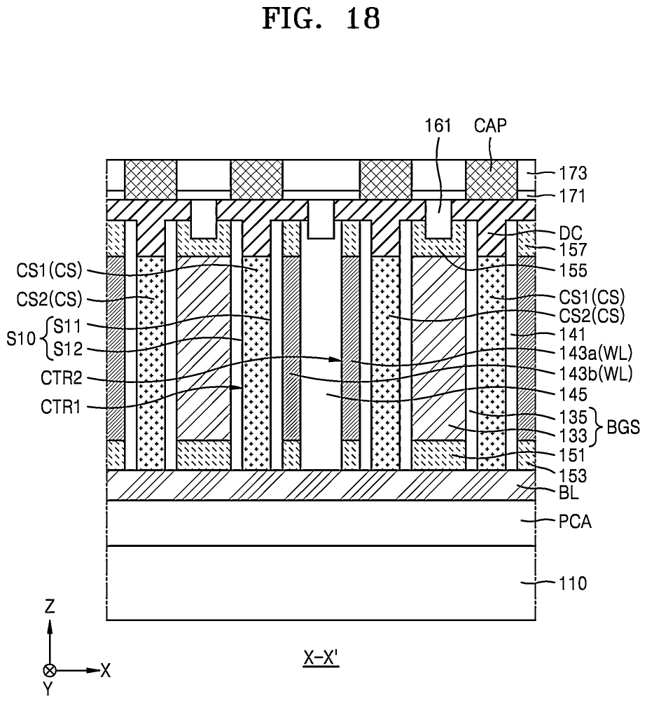

Referring to FIG. 18, an etch stop layer 171 and a capacitor insulating layer 173 may be applied sequentially on a resultant structure shown in FIG. 17. According to embodiments, the etch stop layer 171 may be a silicon nitride layer and the capacitor insulating layer 173 may be a silicon oxide layer. Thereafter, a capacitor structure CAP penetrating or extending into the capacitor insulating layer 173 and the etch stop layer 171 in the vertical direction (e.g., the Z direction) may be formed. The capacitor structure CAP may be connected to any one conductive contact pattern DC selected from among the plurality of conductive contact patterns DC.

As described above, embodiments have been disclosed in the drawings and specification. Although the embodiments have been described by using specific terms in the present specification, the specific terms should be considered for purposes for describing the technical idea of the present disclosure, not for purposes for limiting the meanings or the scope for the present disclosure written in the claims. Therefore, it will be understood by those of ordinary skill in the art that various modifications or other equivalent embodiments may be made from the embodiments. Accordingly, the true technical protecting range of the present disclosure should be determined according to the technical concept of the attached claims.

While the present disclosure has been particularly shown and described with reference to embodiments thereof, it will be understood that various changes in form and details may be made therein without departing from the spirit and scope of the following claims.

What is claimed is:

1. A semiconductor device comprising:
a back gate line that is on a substrate and extends in a first direction;
a plurality of channel structures that are on side walls of the back gate line and spaced apart from each other in a second direction that intersects the first direction;
a word line that at least partially surrounds the plurality of channel structures; and
a bit line on a lower surface of each of the plurality of channel structures,
wherein each of the plurality of channel structures comprises:
a first side wall facing the word line, and
a second side wall that faces the back gate line and is electrically connected to an edge of the first side wall,
wherein the first side wall is curved, and
wherein the second side wall is flat.

2. The semiconductor device of claim 1, wherein a horizontal width of each of the plurality of channel structures decreases from an upper portion of each of the plurality of channel structures to a lower portion of each of the plurality of channel structures.

3. The semiconductor device of claim 1, wherein a horizontal width of each of the plurality of channel structures increases from an upper portion of each of the plurality of channel structures to a lower portion of each of the plurality of channel structures.

4. The semiconductor device of claim 1, further comprising:
a lower back gate capping layer between the back gate line and the bit line; and
a lower word line capping layer between the word line and the bit line.

5. The semiconductor device of claim 1, wherein the first side wall of each of the plurality of channel structures has a circular-arc shape or an elliptical-arc shape.

6. The semiconductor device of claim 1, wherein the plurality of channel structures comprises a first channel structure and a second channel structure, and wherein:
the first channel structure faces a first side wall from among the side walls of the back gate line; and
the second channel structure faces a second side wall from among the side walls of the back gate line,
the first channel structure is symmetrical to the second channel structure with respect to the back gate line, and
the back gate line is between the first channel structure and the second channel structure.

7. The semiconductor device of claim 1, further comprising a back gate insulating layer between the plurality of channel structures and the back gate line.

8. The semiconductor device of claim 7, further comprising a gate dielectric layer between the plurality of channel structures and the word line, wherein:
a first side wall of a first portion of the gate dielectric layer overlaps the plurality of channel structures in the first direction and is curved, and
a second side wall of a second portion of the gate dielectric layer is flat.

9. The semiconductor device of claim 1, further comprising:
a plurality of conductive contact patterns that are respectively on a plurality of upper surfaces of the plurality of channel structures; and
a separation insulation pattern between the plurality of conductive contact patterns.

10. The semiconductor device of claim 9, wherein the back gate line and the word line are spaced apart from the plurality of conductive contact patterns, and wherein the semiconductor device further comprises:
an upper back gate line capping layer on an upper portion of the back gate line; and
an upper word line capping layer on an upper portion of the word line.

11. The semiconductor device of claim 10, further comprising:
a capacitor insulating layer on the plurality of conductive contact patterns; and
a capacitor structure that extends into the capacitor insulating layer and is electrically connected to a conductive contact pattern from among the plurality of conductive contact patterns.

12. A semiconductor device comprising:
a bit line that is on a substrate and extends in a first horizontal direction;
a plurality of channel structures on the bit line;
a back gate line that is on first side walls of the plurality of channel structures and extends in a second horizontal direction that intersects the first horizontal direction; and
a word line that is on second side walls of the plurality of channel structures, at least partially surrounds the plurality of channel structures, and extends in the second horizontal direction,
wherein:
each of the first side walls faces the word line,
each of the second side walls faces the back gate line and is spaced apart from a respective first side wall from among the first side walls,
each of the plurality of channel structures comprises a third side wall that is between and is electrically connected to the respective first side wall and a respective second side wall,
each of the first side walls is curved,
each of the second side walls extends in the second horizontal direction, and
each of the third side walls extends in the first horizontal direction.

13. The semiconductor device of claim 12, wherein a first horizontal width of an upper portion of a first channel structure from among the plurality of channel structures is different from a second horizontal width of a lower portion of the first channel structure.

14. The semiconductor device of claim 12, wherein a first horizontal width of an upper portion of a first channel structure from among the plurality of channel structures is substantially equal to a second horizontal width of a lower portion of the first channel structure.

15. The semiconductor device of claim 12, wherein each of the first side walls has a semi-circular arc shape or a semi-elliptical-arc shape.

16. The semiconductor device of claim 12, further comprising:
a back gate insulating layer between the plurality of channel structures and the back gate line; and
a gate dielectric layer between the plurality of channel structures and the word line,
wherein a first side wall of a first portion of the gate dielectric layer overlaps the plurality of channel structures in the first direction,
wherein a first side wall of a first portion of the word line at least partially surrounds the plurality of channel structures and is curved, and
wherein each of a second side wall of a second portion of the gate dielectric layer and a second side wall of a second portion of the word line is flat and extends in the second horizontal direction.

17. A semiconductor device comprising:
a substrate;
a bit line that is on the substrate and extends in a first horizontal direction;
a plurality of channel structures that are electrically connected to the bit line and extend in a vertical direction from an upper surface of the bit line;
a back gate line that is on first side walls of the plurality of channel structures and extends in a second horizontal direction that intersects the first horizontal direction;
a back gate insulating layer between the plurality of channel structures and the back gate line;
a word line that is on second side walls of the plurality of channel structures, at least partially surrounds the plurality of channel structures, and extends in the second horizontal direction;
a gate dielectric layer between the plurality of channel structures and the word line;
a conductive contact pattern that is on the plurality of channel structures and is electrically connected to a first channel structure among the plurality of channel structures; and
a capacitor structure that is on the conductive contact pattern and electrically connected to the conductive contact pattern,
wherein each of the plurality of channel structures comprises a first side wall that contacts the gate dielectric layer and a second side wall that contacts the back gate insulating layer,
wherein the first side wall is curved, and
wherein the second side wall is flat.

18. The semiconductor device of claim 17, wherein a horizontal width of each of the plurality of channel structures decreases from an upper portion of each of the plurality of channel structures to a lower portion of each of the plurality of channel structures.

19. The semiconductor device of claim 17, wherein a horizontal width of each of the plurality of channel structures increases from an upper portion of each of the plurality of channel structures to a lower portion of each of the plurality of channel structures.

20. The semiconductor device of claim 17, wherein the plurality of channel structures comprises a second channel structure, and wherein:
the first channel structure faces a first side of the back gate line,
the second channel structure faces a second side of the back gate line,
the first channel structure is symmetrical to the second channel structure with respect to the back gate line, and
the first channel structure and the second channel structure are spaced apart in the first horizontal direction.
